(19) United States
(12) Patent Application Publication
(10) Pub. No.: US 2026/0190518 A1
(43) Pub. Date: Jul. 2, 2026

(54) PHOTODETECTION DEVICE AND ELECTRONIC DEVICE

(71) Applicant: SONY SEMICONDUCTOR SOLUTIONS CORPORATION, KANAGAWA (JP)

(72) Inventors: SHUNTA NAKANISHI, KANAGAWA (JP); YUKI HATTORI, KANAGAWA (JP); SATOKO IIDA, KANAGAWA (JP); YOSUKE MOGAMI, KANAGAWA (JP); YUKI SHIRAI, KANAGAWA (JP)

(21) Appl. No.: 18/847,858

(22) PCT Filed: Feb. 3, 2023
(86) PCT No.: PCT/JP2023/003501

§ 371 Date: Sep. 17, 2024

(30) Foreign Application Priority Data
Mar. 25, 2022 (JP) 2022-049930

(51) Int. Cl. H10F 39/00; H10F 39/18

(52) U.S. Cl. CPC H10F 39/8027; H10F 39/024; H10F 39/182; H10F 39/8053; H10F 39/806; H10F 39/8063; H10F 39/811

(57) ABSTRACT

Provided is a photodetection device capable of reducing a floating diffusion dark current in a configuration having a plurality of floating diffusion sections in the same pixel. The photodetection device includes a semiconductor layer and a wiring layer. In the semiconductor layer, a plurality of unit pixels including a first photoelectric conversion part that photoelectrically converts light received according to a first sensitivity and a second photoelectric conversion part that photoelectrically converts light received according to a second sensitivity is arranged in a matrix, the second sensitivity being lower than the first sensitivity. The wiring layer is stacked on a surface of the semiconductor layer opposite to the light incident surface, and includes a readout circuit that outputs a pixel signal based on a charge output from the unit pixel. The semiconductor layer includes a common diffusion region connecting a first diffusion region capable of accumulating a charge photoelectrically converted by the first photoelectric conversion part and a second diffusion region capable of accumulating a charge photoelectrically converted by the second photoelectric conversion part. The readout circuit outputs a pixel signal based on the charge from the common diffusion region.

### TECHNICAL FIELD

The present disclosure relates to a photodetection device and an electronic device including the photodetection device.

### BACKGROUND ART

In order for a photodetection device to obtain good image quality under an environment where a difference in brightness/darkness (brightness difference) of light is large, it is required to have a wide dynamic range, and various types of dynamic range expansion techniques have been conventionally proposed. Among the dynamic range expansion techniques, as a structure for expanding a dynamic range of a pixel, there is a subpixel structure including a large pixel and a small pixel having different sensitivities and including a capacitance for accumulating a charge generated in the small pixel (for example, Patent Document 1).

In the subpixel structure, a large pixel is provided with a thick on-chip lens to increase the sensitivity of the large pixel.

### CITATION LIST

### Patent Document

Patent Document 1: WO 2020/121724 A

### SUMMARY OF THE INVENTION

### Problems to be Solved by the Invention

In the pixel layout of the subpixel in Patent Document 1 described above, since diffusion regions of the large pixel and the small pixel are connected via a wiring layer, the area of the diffusion region is increased. Therefore, in a novel structure equipped with an extra capacitor (EC) drive in which the diffusion region between a reset transistor (RST), a switching transistor (FDG) on the large pixel side, and a switching transistor (FCG) on the small pixel side is used as an accumulation node during an accumulation period, a floating diffusion (FD) dark current or an FD white spot deteriorates, leading to a decrease in a signal noise ratio (SNR).

Furthermore, a difference occurs between the spectral and oblique incidence characteristics of the large pixel and the spectral and oblique incidence characteristics of the small pixel, which causes coloring. In particular, as miniaturization progresses, the characteristic difference becomes larger.

Moreover, if the on-chip lens of the large pixel is thick, optical color mixing from the large pixel to the small pixel increases with respect to the light incident at a high angle due to a PKG structure, and a flare resistance of the small pixel decreases.

The present disclosure has been made in view of such circumstances, and an object thereof is to provide a photodetection device and an electronic device capable of reducing a floating diffusion dark current in a configuration having a plurality of floating diffusion parts in the same pixel.

Furthermore, an object of the present disclosure is to provide a photodetection device and an electronic device capable of reducing a characteristic difference between a large pixel and a small pixel in a subpixel structure.

### Solutions to Problems

An aspect of the present disclosure is a photodetection device including: a semiconductor layer in which a plurality of unit pixels having a first photoelectric conversion part that photoelectrically converts light received according to a first sensitivity and a second photoelectric conversion part that photoelectrically converts light received according to a second sensitivity is arranged in a matrix, the second sensitivity being lower than the first sensitivity; and a wiring layer stacked on a surface of the semiconductor layer on a side opposite to a light incident surface and including a readout circuit that outputs a pixel signal based on a charge output from the unit pixel, in which each of the plurality of unit pixels includes a common diffusion region connecting a first diffusion region capable of accumulating a charge photoelectrically converted by the first photoelectric conversion part and a second diffusion region capable of accumulating a charge photoelectrically converted by the second photoelectric conversion part in a plan view, and the readout circuit outputs a pixel signal based on the charge from the common diffusion region of the unit pixel.

Another aspect of the present disclosure is a photodetection device including: a semiconductor layer in which a plurality of pixels each having a photoelectric conversion part that photoelectrically converts received light is arranged in a matrix; and a wiring layer stacked on a surface of the semiconductor layer on a side opposite to a light incident surface and including a readout circuit that outputs a pixel signal based on a charge output from the pixel, in which each of the plurality of unit pixels includes a diffusion region capable of accumulating a charge photoelectrically converted by the photoelectric conversion part, the readout circuit includes three or more pixel transistors, the three or more pixel transistors sharing the same source region, and the diffusion region is arranged in the source region shared by the three or more pixel transistors.

Furthermore, another aspect of the present disclosure is an electronic device including a photodetection device, the photodetection device including: a semiconductor layer in which a plurality of unit pixels having a first photoelectric conversion part that photoelectrically converts light received according to a first sensitivity and a second photoelectric conversion part that photoelectrically converts light received according to a second sensitivity is arranged in a matrix, the second sensitivity being lower than the first sensitivity; and a wiring layer stacked on a surface of the semiconductor layer on a side opposite to a light incident surface and including a readout circuit that outputs a pixel signal based on a charge output from the unit pixel, in which each of the plurality of unit pixels includes a common diffusion region connecting a first diffusion region capable of accumulating a charge photoelectrically converted by the first photoelectric conversion part and a second diffusion region capable of accumulating a charge photoelectrically converted by the second photoelectric conversion part in a plan view, and the readout circuit outputs a pixel signal based on the charge from the common diffusion region of the unit pixel.

Moreover, another aspect of the present disclosure is an electronic device including a photodetection device, the photodetection device including: a semiconductor layer in which a plurality of pixels each having a photoelectric conversion part that photoelectrically converts received light is arranged in a matrix; and a wiring layer stacked on a surface of the semiconductor layer on a side opposite to a light incident surface and including a readout circuit that outputs a pixel signal based on a charge output from the pixel, in which each of the plurality of unit pixels includes a diffusion region capable of accumulating a charge photoelectrically converted by the photoelectric conversion part, the readout circuit includes three or more pixel transistors, the three or more pixel transistors sharing the same source region, and the diffusion region is arranged in the source region shared by the three or more pixel transistors.

### BRIEF DESCRIPTION OF DRAWINGS

FIG. 1 is a block diagram illustrating an example of a schematic configuration of a photodetection device according to a first embodiment of the present disclosure.

FIG. 2 is a circuit diagram illustrating a configuration example of a pixel unit of the photodetection device according to the first embodiment of the present disclosure.

FIG. 3 is a cross-sectional view for explaining an example of a planar layout of each element constituting a unit pixel in a pixel array section of the photodetection device according to the first embodiment of the present disclosure.

FIG. 4 is a partial longitudinal cross-sectional view illustrating an example of a semiconductor structure of a schematic cross section taken along the cross section A-A′ of the unit pixel illustrated in FIG. 3.

FIG. 5 is a timing chart for explaining an example of a 4AD driving operation of a readout circuit of the photodetection device according to the first embodiment of the present disclosure.

FIG. 6 is a timing chart for explaining an example of a 3AD driving operation in a case where the EC of the readout circuit of the photodetection device according to the first embodiment of the present disclosure is not mounted.

FIG. 7 is a timing chart for explaining an example of a 3AD driving operation in a case where the EC of a readout circuit 20 of a photodetection device 1 according to the first embodiment of the present disclosure is mounted.

FIG. 8 is a circuit diagram illustrating a configuration example of a pixel unit of a photodetection device according to a first modification of the first embodiment of the present disclosure.

FIG. 9 is a cross-sectional view for explaining an example of a planar layout of each element constituting a unit pixel in a pixel array section of the photodetection device according to the first modification of the first embodiment of the present disclosure.

FIG. 10 is a partial longitudinal cross-sectional view illustrating an example of a semiconductor structure of a schematic cross section taken along the cross section A-A′ of the unit pixel illustrated in FIG. 9.

FIG. 11 is a circuit diagram illustrating a configuration example of a pixel unit of a photodetection device according to a second modification of the first embodiment of the present disclosure.

FIG. 12 is a cross-sectional view for explaining an example of a planar layout of each element constituting a unit pixel in a pixel array section of the photodetection device according to the second modification of the first embodiment of the present disclosure.

FIG. 13 is a partial longitudinal cross-sectional view illustrating an example of a semiconductor structure of a schematic cross section taken along the cross section A-A′ of the unit pixel illustrated in FIG. 12.

FIG. 14 is a circuit diagram illustrating a configuration example of a pixel unit of a photodetection device according to a second embodiment of the present disclosure.

FIG. 15 is a cross-sectional view for explaining an example of a planar layout of each element constituting a unit pixel in a pixel array section of the photodetection device according to the second embodiment of the present disclosure.

FIG. 16 is a partial longitudinal cross-sectional view illustrating an example of a semiconductor structure of a schematic cross section taken along the cross section A-A′ of the unit pixel illustrated in FIG. 15.

FIG. 17 is a timing chart for explaining an example of a 4AD driving operation of the readout circuit of the photodetection device according to the second embodiment of the present disclosure.

FIG. 18 is a circuit diagram illustrating a configuration example of a pixel unit of a photodetection device according to a first modification of the second embodiment of the present disclosure.

FIG. 19 is a cross-sectional view for explaining an example of a planar layout of each element constituting a unit pixel in a pixel array section of the photodetection device according to the first modification of the second embodiment of the present disclosure.

FIG. 20 is a partial longitudinal cross-sectional view illustrating an example of a semiconductor structure of a schematic cross section taken along the cross section A-A′ of the unit pixel illustrated in FIG. 19.

FIG. 21 is a circuit diagram illustrating a configuration example of a pixel unit of a photodetection device according to a second modification of the second embodiment of the present disclosure.

FIG. 22 is a cross-sectional view for explaining an example of a planar layout of each element constituting a unit pixel in a pixel array section of the photodetection device according to the second modification of the second embodiment of the present disclosure.

FIG. 23 is a partial longitudinal cross-sectional view illustrating an example of a semiconductor structure of a schematic cross section taken along the cross section A-A′ of the unit pixel illustrated in FIG. 22.

FIG. 24 is a partial longitudinal cross-sectional view illustrating an example of a semiconductor structure of a unit pixel of a photodetection device according to a third embodiment of the present disclosure.

FIG. 25 is a partial longitudinal cross-sectional view illustrating a cross-sectional structure of an on-chip lens as a comparative example of the third embodiment.

FIG. 26 is a cross-sectional view illustrating a process procedure of a method of manufacturing the on-chip lens in the comparative example of the third embodiment.

FIG. 27 is a cross-sectional view illustrating a process procedure of a method of manufacturing an on-chip lens according to the third embodiment of the present disclosure.

FIG. 28 is a partial longitudinal cross-sectional view illustrating an example of a semiconductor structure of a unit pixel of a photodetection device according to a fourth embodiment of the present disclosure.

FIG. 29 is a partial longitudinal cross-sectional view illustrating an example of a semiconductor structure of a unit pixel of a photodetection device according to a fifth embodiment of the present disclosure.

FIG. 30 is a partial longitudinal cross-sectional view illustrating an example of a semiconductor structure of a unit pixel of a photodetection device according to a sixth embodiment of the present disclosure.

FIG. 31 is a partial longitudinal cross-sectional view illustrating an example of a semiconductor structure of a unit pixel of a photodetection device according to a seventh embodiment of the present disclosure.

FIG. 32 is a block diagram illustrating a configuration example of an imaging device as an electronic device to which the present technology is applied.

FIG. 33 is a block diagram illustrating a schematic configuration example of a vehicle control system, which is an example of a mobile object control system to which the technology according to the present disclosure can be applied.

FIG. 34 is a diagram illustrating an example of an installation position of the imaging section illustrated in FIG. 33.

### MODE FOR CARRYING OUT THE INVENTION

Hereinafter, embodiments of the present disclosure will be described with reference to the drawings. In the description of the drawings referred to in the following description, the same or similar parts are denoted by the same or similar reference signs to avoid the description from being redundant. However, it should be noted that the drawings are schematic, and the relationship between thickness and planar dimension, the proportion of thickness of each device or each member, and the like differ from actual ones. Therefore, specific thicknesses and dimensions should be determined in consideration of the following description. Furthermore, it is needless to say that the drawings include portions having different dimensional relationships and ratios.

In the present specification, a “first conductivity type” means one of a P-type or an N-type, and a “second conductivity type” means one of the P-type or the N-type different from the “first conductivity type”. Furthermore, “N” or “P” to which “+” or “−” is added means a semiconductor region having a relatively higher or lower impurity density than that of a semiconductor region to which “+” or “−” is not added. However, even in the semiconductor regions to which the same “N” and “N” are added, it does not mean that the impurity densities of the semiconductor regions are exactly the same.

Furthermore, definition of directions such as upward and downward directions, and the like in the following description is merely the definition for convenience of description, and does not limit the technical idea of the present disclosure. For example, it goes without saying that if a target is observed while being rotated by 90°, the upward and downward directions are converted into rightward and leftward, and if the target is observed while being rotated by 180°, the upward and downward are inverted.

Note that the effects described in the present specification are merely examples and are not limited, and other effects may be provided.

### First Embodiment

### Overall Configuration of Photodetection Device

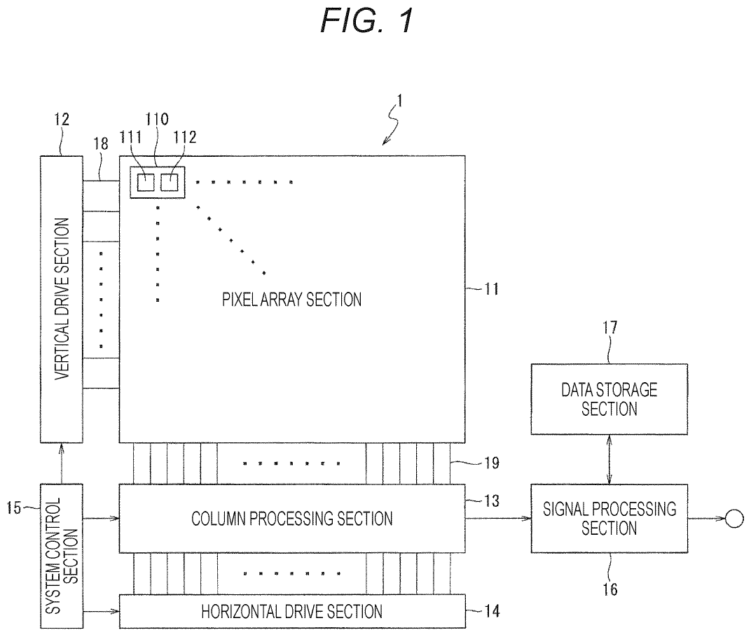

FIG. 1 is a block diagram illustrating an example of a schematic configuration of a photodetection device according to a first embodiment of the present disclosure. A photodetection device 1 is a semiconductor device that converts a charge amount corresponding to the intensity of light formed as an image on each pixel into an electric signal using a photoelectric conversion element such as a photodiode or the like constituting each pixel, and outputs the electric signal as image data, and is configured as, for example, a CMOS image sensor. The photodetection device 1 can be integrally configured as, for example, a system on a chip (SoC) such as a CMOS LSI, but for example, some components described below may be configured as separate LSIs.

As illustrated in the drawing, the photodetection device 1 includes components such as a pixel array section 11, a vertical drive section 12, a column processing section 13, a horizontal drive section 14, a system control section 15, a signal processing section 16, and a data storage section 17, for example.

The pixel array section 11 includes photoelectric conversion element groups such as photodiodes or the like constituting unit pixels 110 arrayed in the horizontal direction (row direction) and the vertical direction (column direction). Each unit pixel 110 includes a large pixel 111 having a large area and a small pixel 112 having a small area. The pixel array section 11 converts a charge amount corresponding to the intensity of the incident light formed as an image on each unit pixel 110 into an electric signal and outputs the electric signal as a pixel signal. The pixel array section 11 can include, for example, effective pixels arranged in a region capable of receiving actual light and dummy pixels arranged outside the region and shielded by metal or the like. Note that an optical element such as a micro-on-chip lens or a color filter that condenses incident light is formed on each unit pixel 110 of the pixel array section 11 (not illustrated).

The vertical drive section 12 includes a shift register, an address decoder, and the like. The vertical drive section 12 supplies a drive signal and the like to each unit pixel 110 via a plurality of pixel drive lines 18, thereby driving each unit pixel 110 of the pixel array section 11, for example, simultaneously or row by row.

The column processing section 13 reads a pixel signal from each pixel via a vertical signal line (VSL) 19 for each pixel column (column) of the pixel array section 11, and performs noise removal processing, correlated double sampling (CDS) processing, analog-to-digital (A/D) conversion processing, and the like. The pixel signal processed by the column processing section 13 is output to the signal processing section 16.

The horizontal drive section 14 includes a shift register, an address decoder, and the like. The horizontal drive section 14 sequentially selects the unit pixels 110 corresponding to the pixel columns of the column processing section 13. By the selective scanning by the horizontal drive section 14, the pixel signals subjected to the signal processing for each unit pixel 110 in the column processing section 13 are sequentially output to the signal processing section 16.

The system control section 15 includes a timing generator that generates various timing signals and the like. The system control section 15 performs drive control of the vertical drive section 12, the column processing section 13, and the horizontal drive section 14 on the basis of, for example, timing signals generated by a timing generator (not illustrated).

The signal processing section 16 performs signal processing such as arithmetic processing or the like on the pixel signal supplied from the column processing section 13 while temporarily storing data in the data storage section 17 as necessary, and outputs an image signal based on each pixel signal. Furthermore, the signal processing section 16 performs signal processing according to the flag output from the column processing section 13.

Note that the photodetection device 1 to which the present technology is applied is not limited to the configuration as described above. For example, the photodetection device 1 may be configured such that the data storage section 17 is arranged at a subsequent stage of the column processing section 13, and the pixel signal output from the column processing section 13 is supplied to the signal processing section 16 via the data storage section 17. Alternatively, the photodetection device 1 may be configured such that the column processing section 13, the data storage section 17, and the signal processing section 16 connected in cascade process the respective pixel signals in parallel.

### Circuit Configuration Example of Pixel Unit

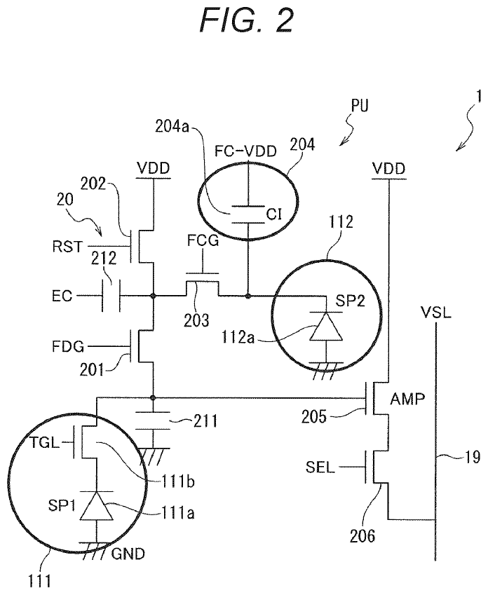

FIG. 2 is a circuit diagram illustrating a configuration example of a pixel unit PU of the photodetection device 1.

As illustrated in FIG. 2, one pixel unit PU includes the large pixel 111, the small pixel 112, and one readout circuit 20. In other words, one readout circuit 20 is shared by the large pixel 111 and the small pixel 112, and the output of the large pixel 111 and the output of the small pixel 112 are input to the shared readout circuit 20.

The large pixel 111 includes a first photoelectric conversion part 111a and a transfer transistor 111b. The small pixel 112 includes a second photoelectric conversion part 112a. The readout circuit 20 includes a first switching transistor 201, a reset transistor 202, a second switching transistor 203, a charge accumulation part 204, an amplification transistor 205, and a selection transistor 206. In the present example, each transistor in the pixel unit PU is an NMOS transistor, but the present invention is not limited thereto.

Furthermore, a plurality of drive lines for supplying various drive signals TGL, FCG, FDG, RST, SEL, and the like to the pixel unit PU is wired, for example, for each pixel row as the pixel drive lines 18 illustrated in FIG. 1. These drive signals are, for example, pulse signals that bring the NMOS transistor into a conductive (on) state at a high potential level and bring the NMOS transistor into a non-conductive (off) state at a low potential level.

The first photoelectric conversion part 111a and the second photoelectric conversion part 112a are, for example, PN-junction photodiodes. Each of the first photoelectric conversion part 111a and the second photoelectric conversion part 112a generates and accumulates a charge corresponding to the amount of received light. In the present example, the area of the light receiving surface of the first photoelectric conversion part 111a is configured to be larger than the area of the light receiving surface of the second photoelectric conversion part 112a, and therefore, the first photoelectric conversion part 111a is configured to cope with higher sensitivity than the second photoelectric conversion part 112a. By using such two types of photodiodes having different sensitivities, the photodetection device 1 can take a large dynamic range of the output voltage level of the pixel signal.

Moreover, the pixel unit PU includes a first floating diffusion part (hereinafter, referred to as a first FD part) 211 and a second floating diffusion part (hereinafter, referred to as a second FD part) 212.

The transfer transistor 111b is an NMOS transistor provided between the first photoelectric conversion part 111a and the first FD part 211. The drive signal TGL is applied to the gate electrode of the transfer transistor 111b. That is, when the drive signal TGL reaches a high potential level, the transfer transistor 111b enters a conductive state, and the charge accumulated in the first photoelectric conversion part 111a is transferred to the first FD part 211 via the transfer transistor 111b.

The second switching transistor 203 is an NMOS transistor provided between the charge accumulation part 204 and the second FD part 212. The drive signal FCG is applied to the gate electrode of the second switching transistor 203. When the drive signal FCG reaches a high potential level, the second switching transistor 203 enters a conductive state, and the potential of the charge accumulation part 204 and the potential of the second FD part 212 are coupled.

The first switching transistor 201 is an NMOS transistor provided between the first FD part 211 and the second FD part 212. The drive signal FDG is applied to the gate electrode of the switching transistor 201. When the drive signal FDG reaches a high potential level, the first switching transistor 201 enters a conductive state, and the potential of the first FD part 211 and the potential of the second FD part 212 are coupled.

The reset transistor 202 is an NMOS transistor provided between the power supply voltage VDD and the second FD part 212. The drive signal RST is applied to the gate electrode of the reset transistor 202. When the drive signal RST reaches a high potential level, the reset transistor 202 enters a conductive state. As a result, according to the potential levels of the drive signals FCG and FDG, the potential of the region where the first FD part 211 and the second FD part 212 are coupled, the potential of the region where the charge accumulation part 204 and the second FD part 212 are coupled, or the potential of the region where the charge accumulation part 204, the first FD part 211, and the second FD part 212 are coupled is reset to the level of the power supply voltage VDD.

The charge accumulation part 204 includes a polysilicon (CI) capacitance 204a. One electrode of the charge accumulation part 204 is connected to the power supply voltage VDD, and the other electrode is connected to the cathode electrode of the second photoelectric conversion part 112a and the drain electrode of the second switching transistor 203. The charge accumulation part 204 accumulates the charge photoelectrically converted by the second photoelectric conversion part 112a.

The first FD part 211 is a diffusion region capable of holding a predetermined charge amount. One electrode of the first FD part 211 is grounded, and the other electrode is connected to each of the drain electrode of the transfer transistor 111b, the drain electrode of the first switching transistor 201, and the gate electrode of the amplification transistor 205. The charge accumulated in the first FD part 211 is read out by being subjected to charge-voltage conversion into a voltage signal.

The second FD part 212 is also a diffusion region capable of holding a predetermined charge amount. In the present embodiment, the charges accumulated in the second FD part 212 are overflowed charges among the charges photoelectrically converted by the first photoelectric conversion part 111a. The second FD part 212 includes wiring lines connected to the source diffusion region of the first switching transistor 201 and the source electrode of the first switching transistor 201, and a wiring capacitance by a metal wiring pattern. The charge accumulated in the second FD part 212 is read out by being subjected to charge-voltage conversion into a voltage signal.

The amplification transistor 205 is an NMOS transistor having the gate electrode connected to the first FD part 211 and the drain electrode connected to the power supply voltage VDD. The amplification transistor 205 serves as an input part of a readout circuit for reading out charges held in the first FD part 211 or the second FD part 212. The source electrode of the amplification transistor 205 is connected to the vertical signal line 19 via the selection transistor 206.

The selection transistor 206 is an NMOS transistor provided between the source electrode of the amplification transistor 205 and the vertical signal line 19. The drive signal SEL is applied to the gate electrode of the selection transistor 206. When the drive signal SEL reaches a high potential level, the selection transistor 206 enters a conductive state, and the unit pixel 110 enters a selected state. As a result, the pixel signal output from the amplification transistor 205 is read out to the vertical signal line 19 via the selection transistor 206.

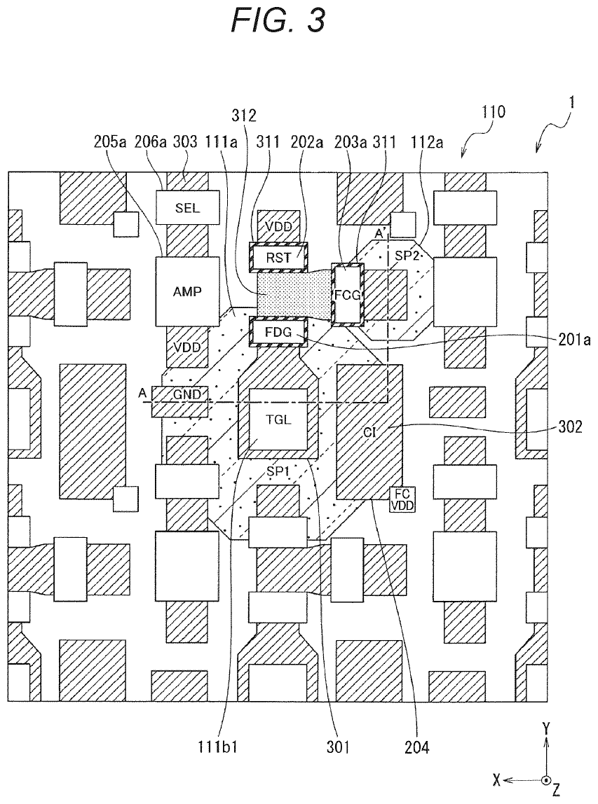

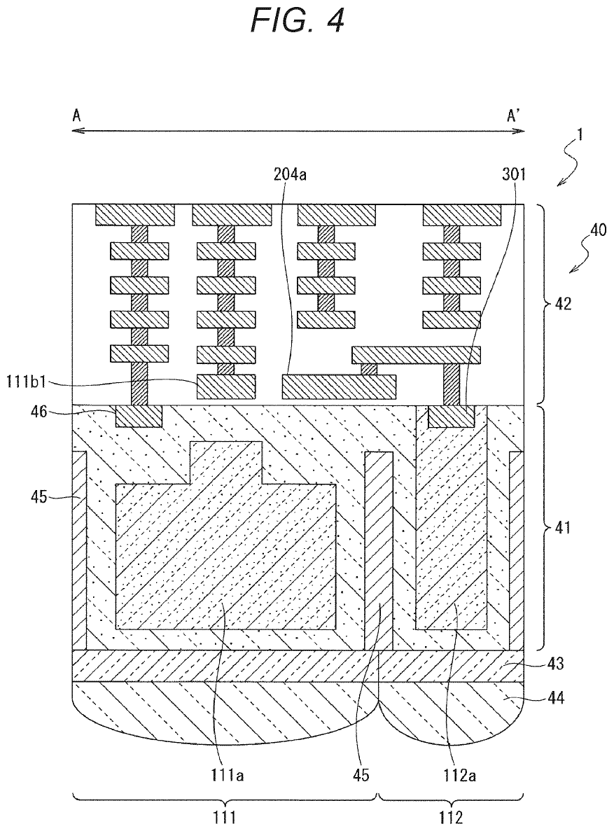

FIG. 3 is a view for explaining an example of a planar layout of each element constituting the unit pixel 110 in the pixel array section 11 of the photodetection device 1 according to the first embodiment of the present disclosure. The drawing illustrates a planar layout when viewed from a surface (front surface) opposite to the incident surface of the unit pixel 110 on which light is incident. Furthermore, FIG. 4 is a partial longitudinal cross-sectional view illustrating an example of a semiconductor structure of a schematic cross section taken along the cross section A-A′ of the unit pixel 110 illustrated in FIG. 3. Note that, in the present disclosure, a plane parallel to the front surface of the unit pixel 110 is referred to as an XY plane, and a direction perpendicular to the XY plane is referred to as a Z direction or a depth direction.

The first photoelectric conversion part 111a is formed in the substantially central portion of the unit pixel 110. In the present example, the first photoelectric conversion part 111a is formed in an octagonal shape. The second photoelectric conversion part 112a is formed on the Y direction side of the first photoelectric conversion part 111a. A gate electrode 11b1 of the transfer transistor 111b is formed on an active region 301 in the substantially central portion of the first photoelectric conversion part 111a.

The active region 301 is an ion implantation region, extends in the Y direction from the substantially central portion of the first photoelectric conversion part 111a, and further extends to the substantially central portion of the second photoelectric conversion part 112a. In the active region 301, a gate electrode 201a of the first switching transistor 201, a gate electrode 202a of the reset transistor 202, and a gate electrode 203a of the second switching transistor 203 are formed. Therefore, a drive signal is applied to the gate electrode 201a of the first switching transistor 201, the gate electrode 202a of the reset transistor 202, and the gate electrode 203a of the second switching transistor 203, so that the first switching transistor 201, the reset transistor 202, and the second switching transistor 203 are electrically connected on the active region 301.

A sidewall 311 is formed on a sidewall of each of the gate electrode 201a of the first switching transistor 201, the gate electrode 202a of the reset transistor 202, and the gate electrode 203a of the second switching transistor 203. The sidewall 311 includes an insulating film such as a silicon nitride film (SiN) or a silicon oxide film (SiO2), for example.

In the first embodiment of the present disclosure, a common diffusion region 312 (in FIG. 3, dots are illustrated) of the first photoelectric conversion part 111a and the second photoelectric conversion part 112a is formed between the gate electrode 201a of the first switching transistor 201, the gate electrode 202a of the reset transistor 202, and the gate electrode 203a of the second switching transistor 203. The common diffusion region 312 is a diffusion region in which the first FD part 211 and the second FD part 212 are connected together. The common diffusion region 312 is formed in the active region 301 after the sidewall 311 is formed in each of the gate electrode 201a of the first switching transistor 201, the gate electrode 202a of the reset transistor 202, and the gate electrode 203a of the second switching transistor 203. Therefore, the area of the common diffusion region 312 can be minimized.

The capacitance 204a of the charge accumulation part 204 is formed in an active region 302. Furthermore, a gate electrode 205a of the amplification transistor 205 and a gate electrode 206a of the selection transistor 206 are formed in an active region 303. The capacitance 204a of the charge accumulation part 204 is connected to the drain electrode of the second switching transistor 203 via a wiring layer described later. The gate electrode 205a of the amplification transistor 205 is connected to the drain electrode of the transfer transistor 111b and the drain electrode of the first switching transistor 201 via the wiring layer described later.

A semiconductor structure 40 of the unit pixel 110 schematically includes, for example, a photoelectric conversion layer 41 as a semiconductor layer, a wiring layer 42, a color filter 43, and an on-chip lens 44. Such a semiconductor structure 40 can be configured, for example, by integrally bonding a first silicon substrate including the photoelectric conversion layer 41 and a second silicon substrate including the wiring layer 42 and various logic circuits (not illustrated).

The on-chip lens 44 is an optical lens for efficiently condensing light incident on the photodetection device 1 from the outside and forming an image on each of the large pixels 111 (that is, the first photoelectric conversion part 111a) and the small pixels 112 (that is, the second photoelectric conversion part 112a) of the photoelectric conversion layer 41. The on-chip lens 44 is typically arranged for each of the large pixels 111 and the small pixels 112.

The color filter 43 is an optical filter that selectively transmits light of a predetermined wavelength of the light condensed by the on-chip lens 44. In the present example, four color filters 43 that selectively transmit wavelengths of red light, green light, blue light, and near-infrared light are used, but the present invention is not limited thereto. The color filter 43 corresponding to any color (wavelength) is arranged in each of the large pixels 111 and the small pixels 112.

The photoelectric conversion layer 41 is a functional layer in which the first photoelectric conversion part 111a, the second photoelectric conversion part 112a, the transfer transistor 111b, and the like are formed. The first photoelectric conversion part 111a and the second photoelectric conversion part 112a of the photoelectric conversion layer 41 generate a charge amount corresponding to the intensity of light incident via the on-chip lens 44 and the color filter 43, convert the charge amount into an electric signal, and output the electric signal as a pixel signal. Note that part of the light (for example, near-infrared light or the like) incident on an incident surface of the photoelectric conversion layer 41 can transmit a surface (that is, the front surface) opposite to the incident surface (that is, the back surface).

The photoelectric conversion layer 41 is manufactured on a silicon substrate by a semiconductor manufacturing process. The first photoelectric conversion part 111a, the second photoelectric conversion part 112a, and the transfer transistor 111b are electrically connected to a predetermined metal wiring in the wiring layer 42. Furthermore, in the photoelectric conversion layer 41, an inter-pixel separation portion 45 that separates each of the large pixels 111 and the small pixels 112 can be formed. The inter-pixel separation portion 45 has, for example, a trench structure formed by etching processing. The inter-pixel separation portion 45 prevents light incident on the large pixel 111 from entering the adjacent small pixel 112, and prevents light incident on the small pixel 112 from entering the adjacent large pixel 111. Moreover, the photoelectric conversion layer 41 is provided with a contact 46 for grounding to GND (ground) on the front surface side.

The wiring layer 42 is a layer in which a metal wiring pattern for transmitting power and various drive signals to each of the large pixels 111 and the small pixels 112 in the photoelectric conversion layer 41 and transmitting pixel signals read from each of the large pixels 111 and the small pixels 112 is formed. The wiring layer 42 can typically include a plurality of layers of metal wiring patterns stacked together with an interlayer insulating film interposed therebetween. Furthermore, the stacked metal wiring patterns are electrically connected via, for example, vias, as necessary. The wiring layer 42 includes, for example, metal such as aluminum (Al) or copper (Cu). On the other hand, the interlayer insulating film includes, for example, silicon oxide or the like. Moreover, the wiring layer 42 includes the readout circuit 20 and can include a gate electrode 111b1 of the transfer transistor 111b. Furthermore, the wiring layer 42 includes a polysilicon capacitance 204a of the charge accumulation part 204.

### Operation of Photodetection Device 1

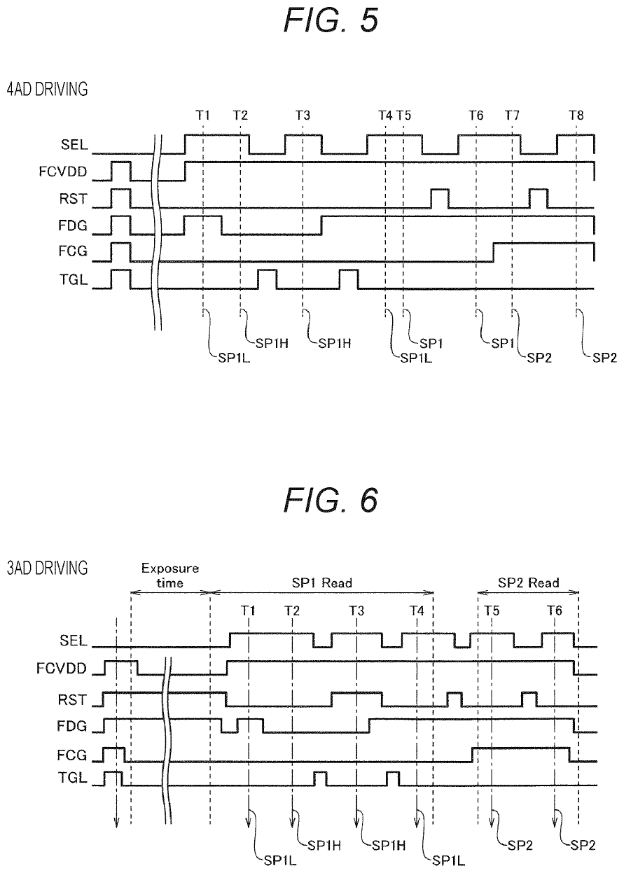

FIG. 5 is a timing chart for explaining an example of a 4AD driving operation of the readout circuit 20 of the photodetection device 1 according to the first embodiment of the present disclosure, and specifically, is a timing chart illustrating an example of readout processing of a pixel signal from the unit pixel 110. In the drawing, timing charts of the drive signals SEL, RST, FDG, TGL, FCG, and the power supply FCVDD for the unit pixel 110 are illustrated. The processing is performed in a predetermined scanning order after a predetermined time from when exposure processing is performed, for example, for each unit pixel row or each of a plurality of unit pixel rows of the pixel array section 11.

Next, at time T1, a pixel signal SP1L based on the potential due to the coupling between the first FD part 211 and the second FD part 212 is output to the vertical signal line 19 via the amplification transistor 205 and the selection transistor 206. Note that the pixel signal SP1L is a potential level in an initial state immediately after the start of reading.

Next, at time T2, the drive signal FDG reaches a low potential level, and the first switching transistor 201 enters a non-conductive state. As a result, the potential coupling between the first FD part 211 and the second FD part 212 is released. Then, a pixel signal SP1H based on the potential of the first FD part 211 is output to the vertical signal line 19 via the amplification transistor 205 and the selection transistor 206.

Next, the drive signal SEL reaches a low potential level, and the selection transistor 206 enters a non-conductive state. As a result, reading of the pixel signal from the unit pixel 110 is temporarily stopped.

Next, the drive signal TGL reaches a high potential level, and the transfer transistor 111b enters a conductive state. As a result, the charge generated and accumulated in the first photoelectric conversion part 111a during the exposure period is transferred to the first FD part 211 via the transfer transistor 111b.

Next, the drive signal TGL reaches a low potential level, and the transfer transistor 111b enters a non-conductive state. As a result, the transfer of the charge from the first photoelectric conversion part 111a to the first FD part 211 is stopped, and preparation for reading the pixel signal based on the charge of the first FD part 211 is completed.

Next, the drive signal SEL reaches a high potential level, and the selection transistor 206 enters a conductive state.

Next, at time T3, a pixel signal SP1H based on the potential of the first FD part 211 is output to the vertical signal line 19 via the amplification transistor 205 and the selection transistor 206. The pixel signal SP1H is a D-phase pixel signal for the P-phase pixel signal SP1H read at time T3, which is generated by the first photoelectric conversion part 111a during the exposure period and is based on the charge accumulated in the first FD part 211.

Next, the drive signal SEL reaches a low potential level and the selection transistor 206 enters a non-conductive state, and the drive signal FDG reaches a high potential level and the first switching transistor 201 enters a conductive state. As a result, reading of the pixel signal from the unit pixel 110 is temporarily stopped, and the potential of the first FD part 211 and the potential of the second FD part 212 are coupled.

Next, the drive signal TGL reaches a high potential level, and the transfer transistor 111b enters a conductive state. As a result, charges that has not been transferred from the first photoelectric conversion part 111a is transferred to the region coupled with the first FD part 211 and the second FD part 212 via the transfer transistor 111b.

Next, the drive signal TGL reaches a low potential level, and the transfer transistor 111b reaches a low potential level. As a result, the transfer of the remaining charges from the first photoelectric conversion part 111a to the region where the first FD part 211 and the second FD part 212 are coupled is stopped.

Next, the drive signal SEL reaches a high potential level, and the selection transistor 206 enters a conductive state.

Next, at time T4, a pixel signal SP1L based on the potential due to the coupling between the first FD part 211 and the second FD part 212 is output to the vertical signal line 19 via the amplification transistor 205 and the selection transistor 206. The pixel signal SP1L is a D-phase pixel signal for the P-phase pixel signal SP1L output at time T1.

Next, at time T5, a D-phase pixel signal SP1 based on the potential due to the coupling between the first FD part 211 and the second FD part 212 is output to the vertical signal line 19 via the amplification transistor 205 and the selection transistor 206.

Next, the drive signal SEL reaches a low potential level, and the selection transistor 206 enters a non-conductive state.

Next, the drive signal RST reaches a high potential level, and the reset transistor 202 enters a conductive state. As a result, the potential of the region where the first FD part 211 and the second FD part 212 are coupled is reset to the level of the power supply voltage VDD.

Next, the drive signal RST reaches a low potential level, and the reset transistor 202 enters a non-conductive state.

Next, the drive signal SEL reaches a high potential level, and the selection transistor 206 enters a conductive state.

Next, at time T6, a pixel signal SP1 based on the potential due to the coupling between the first FD part 211 and the second FD part 212 is output to the vertical signal line 19 via the amplification transistor 205 and the selection transistor 206. The pixel signal SP1 is a P-phase pixel signal for the D-phase pixel signal SP1 output at time T5.

Next, the drive signal FCG reaches a high potential level, and the second switching transistor 203 enters a conductive state. As a result, the potential of the first FD part 211, the potential of the second FD part 212, and the potential of the charge accumulation part 204 are coupled.

Subsequently, at time T7, a pixel signal SP2 based on the potential due to the coupling of the first FD part 211, the second FD part 212, and the charge accumulation part 204 is output to the vertical signal line 19 via the amplification transistor 205 and the selection transistor 206. The pixel signal SP2 is a D-phase pixel signal corresponding to bright light including charges accumulated in the second photoelectric conversion part 112a.

Next, the drive signal SEL reaches a low potential level, and the selection transistor 206 enters a non-conductive state.

Next, the drive signal RST reaches a high potential level, and the reset transistor 202 enters a conductive state. As a result, the potential of the region where the first FD part 211, the second FD part 212, and the charge accumulation part 204 are coupled is reset to the level of the power supply voltage VDD.

Next, the drive signal RST reaches a low potential level, and the reset transistor 202 enters a non-conductive state.

Next, the drive signal SEL reaches a high potential level, and the selection transistor 206 enters a conductive state.

Subsequently, at time T8, a pixel signal SP2 based on the potential due to the coupling of the first FD part 211, the second FD part 212, and the charge accumulation part 204 is output to the vertical signal line 19 via the amplification transistor 205 and the selection transistor 206. The pixel signal SP2 is a P-phase pixel signal for the D-phase pixel signal SP2 output at time T7.

FIG. 6 is a timing chart for explaining an example of a 3AD driving operation in a case where an extra capacitor (EC) of the readout circuit 20 of the photodetection device 1 according to the first embodiment of the present disclosure is not mounted, and specifically, is a timing chart illustrating an example of readout processing of a pixel signal from the unit pixel 110.

At time T1, a pixel signal SP1L based on the potential due to the coupling between the first FD part 211 and the second FD part 212 is output to the vertical signal line 19 via the amplification transistor 205 and the selection transistor 206. Note that the pixel signal SP1L is a potential level in an initial state immediately after the start of reading.

Next, at time T2, the drive signal FDG reaches a low potential level, and the first switching transistor 201 enters a non-conductive state. As a result, the potential coupling between the first FD part 211 and the second FD part 212 is released. Then, a pixel signal SP1H based on the potential of the first FD part 211 is output to the vertical signal line 19 via the amplification transistor 205 and the selection transistor 206.

Next, the drive signal SEL reaches a low potential level, and the selection transistor 206 enters a non-conductive state. As a result, reading of the pixel signal from the unit pixel 110 is temporarily stopped.

Next, the drive signal TGL reaches a high potential level, and the transfer transistor 111b enters a conductive state. As a result, the charge generated and accumulated in the first photoelectric conversion part 111a during the exposure period is transferred to the first FD part 211 via the transfer transistor 111b.

Next, the drive signal TGL reaches a low potential level, and the transfer transistor 111b enters a non-conductive state. As a result, the transfer of the charge from the first photoelectric conversion part 111a to the first FD part 211 is stopped, and preparation for reading the pixel signal based on the charge of the first FD part 211 is completed.

Next, the drive signal SEL reaches a high potential level, and the selection transistor 206 enters a conductive state.

Next, at time T3, a pixel signal SP1H based on the potential of the first FD part 211 is output to the vertical signal line 19 via the amplification transistor 205 and the selection transistor 206. The pixel signal SP1H is a D-phase pixel signal for the P-phase pixel signal SPH1 read at time T2, which is generated by the first photoelectric conversion part 111a during the exposure period and is based on the charge accumulated in the first FD part 211.

Next, the drive signal SEL reaches a low potential level and the selection transistor 206 enters a non-conductive state, and the drive signal FDG reaches a high potential level and the first switching transistor 201 enters a conductive state. As a result, reading of the pixel signal from the unit pixel 110 is temporarily stopped, and the potential of the first FD part 211 and the potential of the second FD part 212 are coupled.

Next, the drive signal TGL reaches a high potential level, and the transfer transistor 111b enters a conductive state. As a result, charges that has not been transferred from the first photoelectric conversion part 111a is transferred to the region coupled with the first FD part 211 and the second FD part 212 via the transfer transistor 111b.

Next, the drive signal TGL reaches a low potential level, and the transfer transistor 111b reaches a low potential level. As a result, the transfer of the remaining charges from the first photoelectric conversion part 111a to the region where the first FD part 211 and the second FD part 212 are coupled is stopped.

Next, the drive signal SEL reaches a high potential level, and the selection transistor 206 enters a conductive state.

Next, at time T4, a pixel signal SP1L based on the potential due to the coupling between the first FD part 211 and the second FD part 212 is output to the vertical signal line 19 via the amplification transistor 205 and the selection transistor 206. The pixel signal SP1L is a D-phase pixel signal for the P-phase pixel signal SP1L output at time T1.

Next, the drive signal SEL reaches a low potential level, and the selection transistor 206 enters a non-conductive state.

Next, the drive signal RST reaches a high potential level, and the reset transistor 202 enters a conductive state. As a result, the potential of the region where the first FD part 211 and the second FD part 212 are coupled is reset to the level of the power supply voltage VDD.

Next, the drive signal RST reaches a low potential level, and the reset transistor 202 enters a non-conductive state.

Next, the drive signal SEL reaches a high potential level, and the selection transistor 206 enters a conductive state.

Next, the drive signal FCG reaches a high potential level, and the second switching transistor 203 enters a conductive state. As a result, the potential of the first FD part 211, the potential of the second FD part 212, and the potential of the charge accumulation part 204 are coupled.

Subsequently, at time T5, a pixel signal SP2 based on the potential due to the coupling of the first FD part 211, the second FD part 212, and the charge accumulation part 204 is output to the vertical signal line 19 via the amplification transistor 205 and the selection transistor 206. The pixel signal SP2 is a D-phase pixel signal corresponding to bright light including charges accumulated in the second photoelectric conversion part 112a.

Next, the drive signal SEL reaches a low potential level, and the selection transistor 206 enters a non-conductive state.

Next, the drive signal RST reaches a high potential level, and the reset transistor 202 enters a conductive state. As a result, the potential of the region where the first FD part 211, the second FD part 212, and the charge accumulation part 204 are coupled is reset to the level of the power supply voltage VDD.

Next, the drive signal RST reaches a low potential level, and the reset transistor 202 enters a non-conductive state.

Next, the drive signal SEL reaches a high potential level, and the selection transistor 206 enters a conductive state.

Subsequently, at time T6, a pixel signal SP2 based on the potential due to the coupling of the first FD part 211, the second FD part 212, and the charge accumulation part 204 is output to the vertical signal line 19 via the amplification transistor 205 and the selection transistor 206. The pixel signal SP2 is a P-phase pixel signal for the D-phase pixel signal SP2 output at time T7.

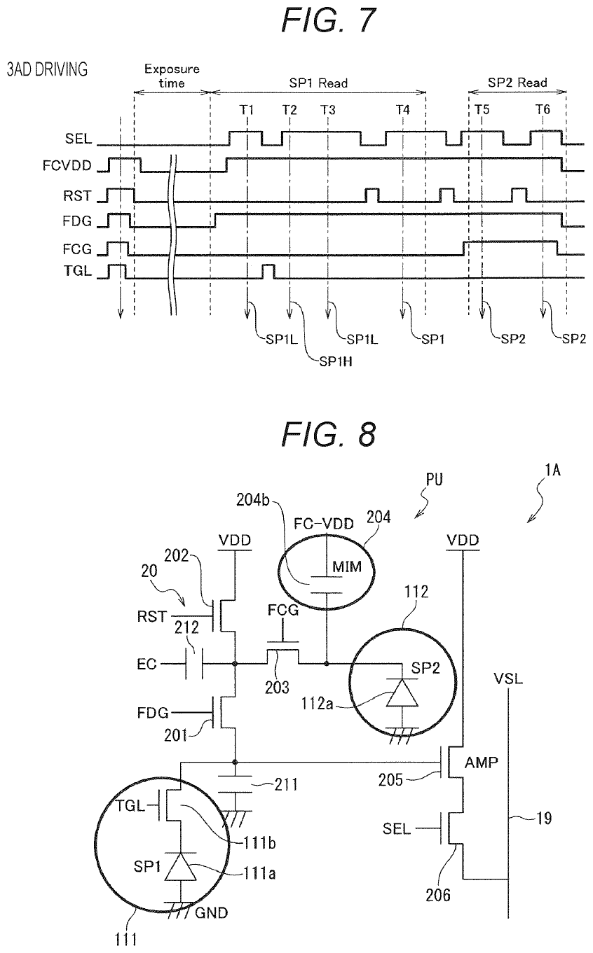

FIG. 7 is a timing chart for explaining an example of a 3AD driving operation in a case where the EC of the readout circuit 20 of the photodetection device 1 according to the first embodiment of the present disclosure is mounted, and specifically, is a timing chart illustrating an example of readout processing of a pixel signal from the unit pixel 110.

In this example, during the exposure period, the first switching transistor 201 is in a conductive state. As a result, during the exposure period, a region where the first FD part 211 and the second FD part 212 are coupled functions as an accumulation node. At time T1, a pixel signal SP1L based on the potential due to the coupling between the first FD part 211 and the second FD part 212 is output to the vertical signal line 19 via the amplification transistor 205 and the selection transistor 206. Note that the pixel signal SP1L is a potential level in an initial state immediately after the start of reading.

Next, the drive signal TGL reaches a high potential level, and the transfer transistor 111b enters a conductive state. As a result, charges that has not been transferred from the first photoelectric conversion part 111a is transferred to the region coupled with the first FD part 211 and the second FD part 212 via the transfer transistor 111b.

Next, the drive signal TGL reaches a low potential level, and the transfer transistor 111b reaches a low potential level. As a result, the transfer of the remaining charges from the first photoelectric conversion part 111a to the region where the first FD part 211 and the second FD part 212 are coupled is stopped.

Next, the drive signal SEL reaches a high potential level, and the selection transistor 206 enters a conductive state.

Next, at time T2, a pixel signal SP1H based on the potential due to the coupling between the first FD part 211 and the second FD part 212 is output to the vertical signal line 19 via the amplification transistor 205 and the selection transistor 206. The pixel signal SP1H is a D-phase pixel signal for the P-phase pixel signal SP1L output at time T1.

Next, at time T3, a pixel signal SP1L based on the potential due to the coupling between the first FD part 211 and the second FD part 212 is output to the vertical signal line 19 via the amplification transistor 205 and the selection transistor 206.

Next, the drive signal SEL reaches a low potential level, and the selection transistor 206 enters a non-conductive state.

Next, the drive signal RST reaches a high potential level, and the reset transistor 202 enters a conductive state. As a result, the potential of the region where the first FD part 211 and the second FD part 212 are coupled is reset to the level of the power supply voltage VDD.

Next, the drive signal RST reaches a low potential level, and the reset transistor 202 enters a non-conductive state.

Next, the drive signal SEL reaches a high potential level, and the selection transistor 206 enters a conductive state.

Next, at time T4, a pixel signal SP1 based on the potential due to the coupling between the first FD part 211 and the second FD part 212 is output to the vertical signal line 19 via the amplification transistor 205 and the selection transistor 206.

Next, the drive signal SEL reaches a low potential level, and the selection transistor 206 enters a non-conductive state.

Next, the drive signal RST reaches a high potential level, and the reset transistor 202 enters a conductive state. As a result, the potential of the region where the first FD part 211 and the second FD part 212 are coupled is reset to the level of the power supply voltage VDD.

Next, the drive signal RST reaches a low potential level, and the reset transistor 202 enters a non-conductive state.

Next, the drive signal SEL reaches a high potential level, and the selection transistor 206 enters a conductive state.

Next, the drive signal FCG reaches a high potential level, and the second switching transistor 203 enters a conductive state. As a result, the potential of the first FD part 211, the potential of the second FD part 212, and the potential of the charge accumulation part 204 are coupled.

Subsequently, at time T5, a pixel signal SP2 based on the potential due to the coupling of the first FD part 211, the second FD part 212, and the charge accumulation part 204 is output to the vertical signal line 19 via the amplification transistor 205 and the selection transistor 206. The pixel signal SP2 is a D-phase pixel signal corresponding to bright light including charges accumulated in the second photoelectric conversion part 112a.

Next, the drive signal SEL reaches a low potential level, and the selection transistor 206 enters a non-conductive state.

Next, the drive signal RST reaches a high potential level, and the reset transistor 202 enters a conductive state. As a result, the potential of the region where the first FD part 211, the second FD part 212, and the charge accumulation part 204 are coupled is reset to the level of the power supply voltage VDD.

Next, the drive signal RST reaches a low potential level, and the reset transistor 202 enters a non-conductive state.

Next, the drive signal SEL reaches a high potential level, and the selection transistor 206 enters a conductive state.

Subsequently, at time T6, a pixel signal SP2 based on the potential due to the coupling of the first FD part 211, the second FD part 212, and the charge accumulation part 204 is output to the vertical signal line 19 via the amplification transistor 205 and the selection transistor 206. The pixel signal SP2 is a P-phase pixel signal for the D-phase pixel signal SP2 output at time T7.

### Effects Produced by First Embodiment

As described above, according to the first embodiment, in a plan view, the first FD part 211 formed in the photoelectric conversion layer 41 and the second FD part 212 are connected to form one common diffusion region 312 in the active region 301, so that the area of the common diffusion region 312 can be reduced with respect to the layout in which the first FD part 211 and the second FD part 212 are coupled via the wiring layer 42, and the FD dark current can be reduced. Furthermore, since the number of diffusion regions can be reduced on the layout, it is advantageous for reducing the size of the unit pixel 110.

Furthermore, according to the first embodiment, the bias dependency of the capacitance value can be reduced by using the polysilicon capacitance 204a as the capacitance connected to the common diffusion region 312.

### First Modification of First Embodiment

FIG. 8 is a circuit diagram illustrating a configuration example of a pixel unit PU of a photodetection device 1A according to a first modification of the first embodiment of the present disclosure. In FIG. 8, the same components as those in FIG. 2 described above are denoted by the same reference signs, and detailed description thereof is omitted.

In the first modification, the charge accumulation part 204 includes a metal insulator metal (MIM) capacitance 204b.

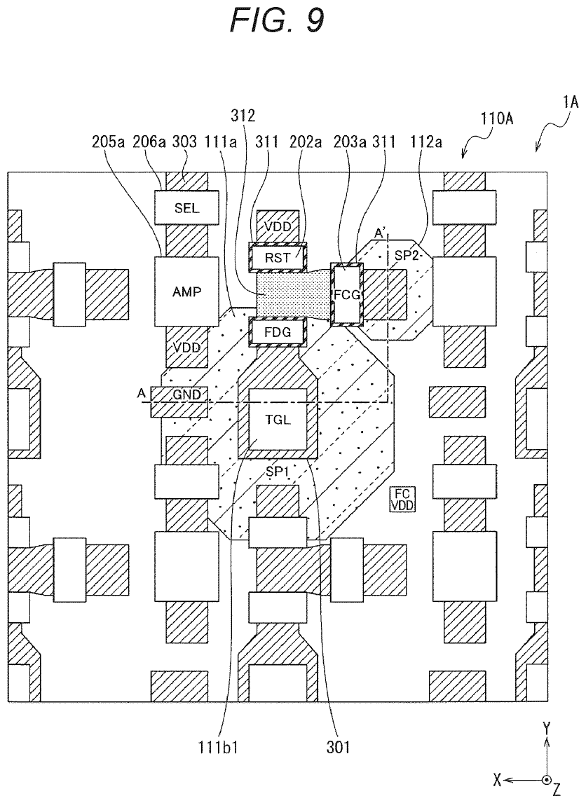

FIG. 9 is a view for explaining an example of a planar layout of each element constituting a unit pixel 110A in the pixel array section 11 of the photodetection device 1A according to the first modification of the first embodiment of the present disclosure. In FIG. 9, the same components as those in FIG. 3 described above are denoted by the same reference signs, and detailed description thereof is omitted.

In the first modification, since the MIM capacitance 204b is formed using the metal wiring pattern of the wiring layer 42, the active region 302 is unnecessary.

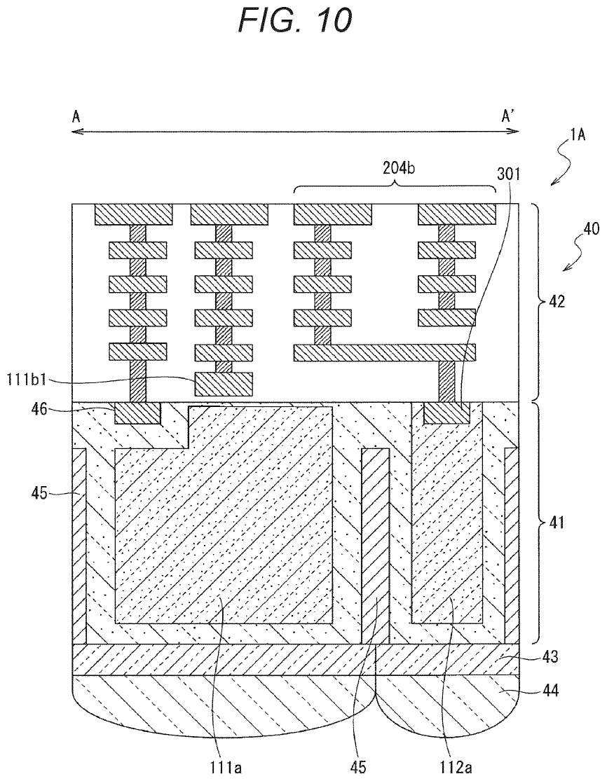

Furthermore, FIG. 10 is a partial longitudinal cross-sectional view illustrating an example of a semiconductor structure of a schematic cross section taken along the cross section A-A′ of the unit pixel 110A illustrated in FIG. 9. In FIG. 10, the same components as those in FIG. 4 above are denoted by the same reference numerals, and a detailed description thereof is omitted.

The MIM capacitance 204b includes the same material as the metal wiring pattern of the wiring layer 42.

### Effects Produced by First Modification of First Embodiment

As described above, according to the first modification of the first embodiment, effects similar to the effects produced by the first embodiment described above can be obtained.

### Second Modification of First Embodiment

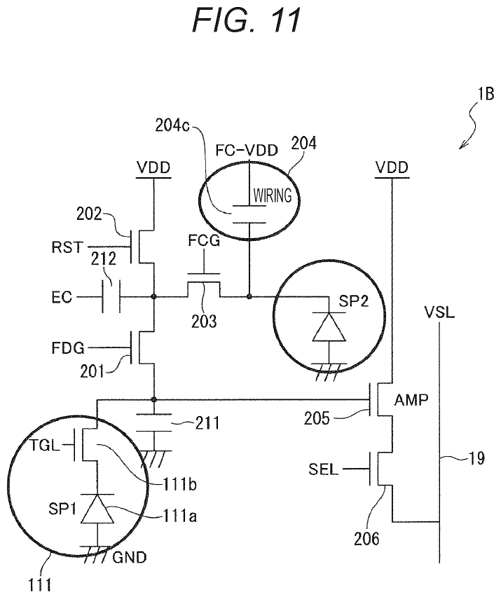

FIG. 11 is a circuit diagram illustrating a configuration example of a pixel unit PU of a photodetection device 1B according to a second modification of the first embodiment of the present disclosure. In FIG. 11, the same components as those in FIG. 2 described above are denoted by the same reference signs, and detailed description thereof is omitted.

In the second modification, the charge accumulation part 204 includes a wiring capacitance 204c.

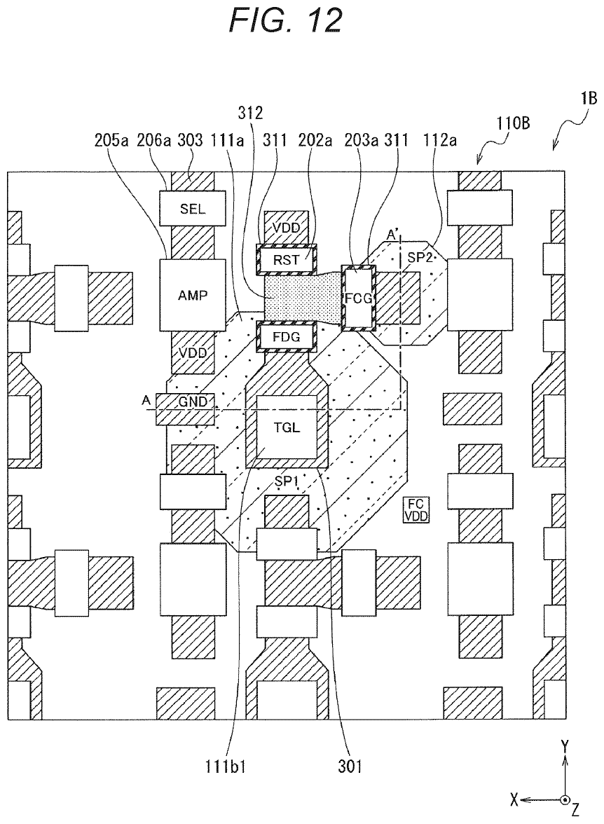

FIG. 12 is a view for explaining an example of a planar layout of each element constituting a unit pixel 110B in the pixel array section 11 of the photodetection device 1B according to the second modification of the first embodiment of the present disclosure. In FIG. 12, the same components as those in FIG. 3 described above are denoted by the same reference signs, and detailed description thereof is omitted.

In the second modification, since the wiring capacitance 204c is formed using the metal wiring pattern of the wiring layer 42, the active region 302 is unnecessary.

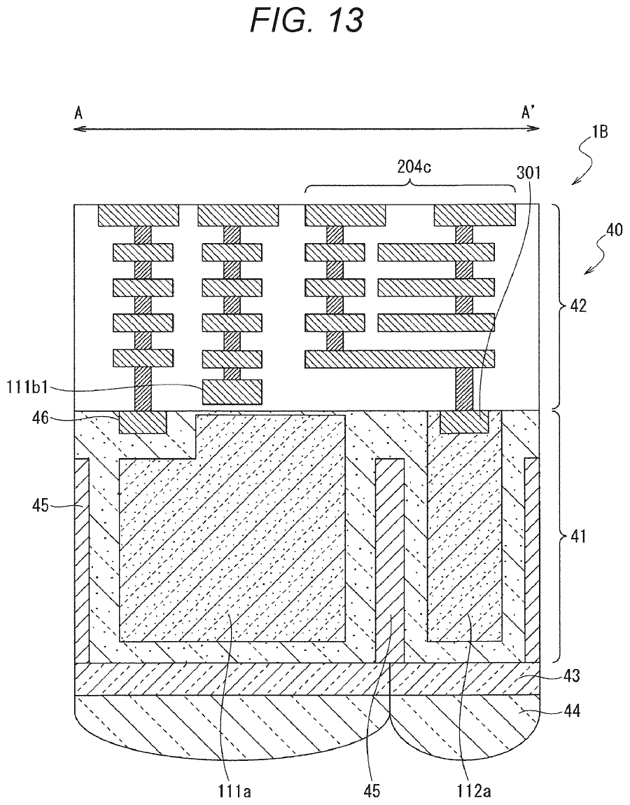

Furthermore, FIG. 13 is a partial longitudinal cross-sectional view illustrating an example of a semiconductor structure of a schematic cross section taken along the cross section A-A′ of the unit pixel 110B illustrated in FIG. 12. In FIG. 13, the same components as those in FIG. 4 described above are denoted by the same reference signs, and detailed description thereof is omitted.

The wiring capacitance 204c includes the same material as the metal wiring pattern of the wiring layer 42.

### Effects Produced by Second Modification of First Embodiment

As described above, according to the second modification of the first embodiment, effects similar to the effects produced by the first embodiment described above can be obtained.

### Second Embodiment

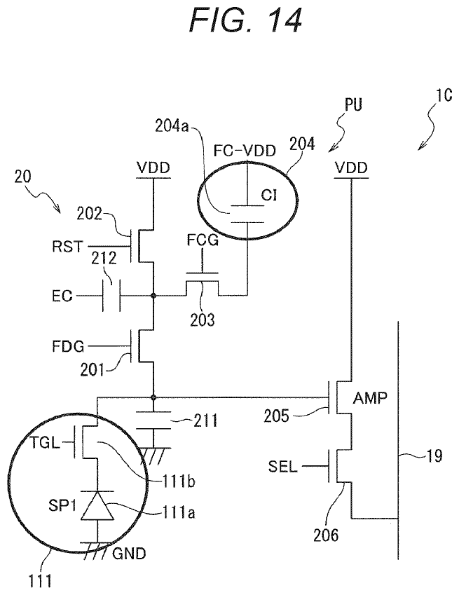

FIG. 14 is a circuit diagram illustrating a configuration example of a pixel unit PU of a photodetection device 1C according to a second embodiment of the present disclosure. In FIG. 14, the same components as those in FIG. 2 described above are denoted by the same reference signs, and detailed description thereof is omitted.

The second embodiment of the present disclosure is different from the first embodiment described above in that the small pixel 112 including the second photoelectric conversion part 112a is removed.

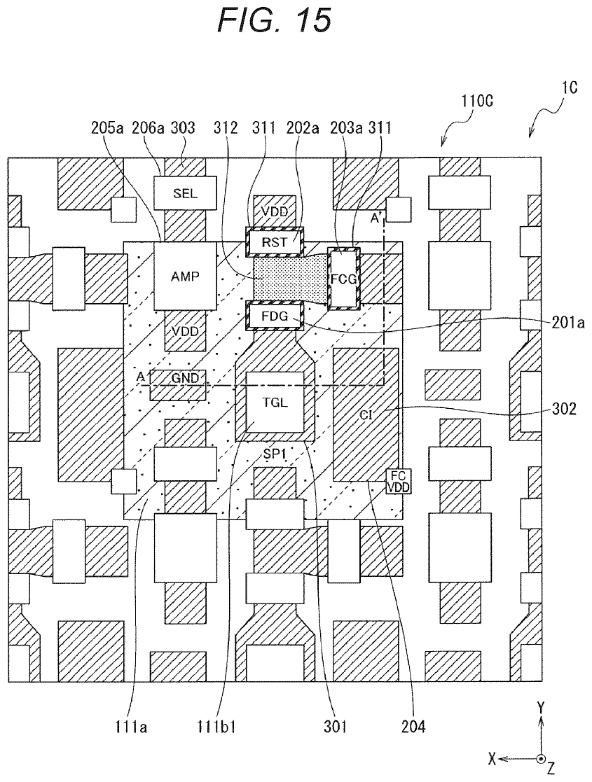

FIG. 15 is a view for explaining an example of a planar layout of each element constituting a unit pixel 110C in the pixel array section 11 of the photodetection device 1C according to the second embodiment of the present disclosure. In FIG. 15, the same components as those in FIG. 3 described above are denoted by the same reference signs, and detailed description thereof is omitted.

The first photoelectric conversion part 111a is formed in the substantially central portion of the unit pixel 110. In the present example, the first photoelectric conversion part 111a is formed in a square shape. The gate electrode 11b1 of the transfer transistor 111b is formed on the active region 301 in the substantially central portion of the first photoelectric conversion part 111a.

The active region 301 is the ion implantation region and extends in the Y direction from the substantially central portion of the first photoelectric conversion part 111a. In the active region 301, the gate electrode 201a of the first switching transistor 201, the gate electrode 202a of the reset transistor 202, and the gate electrode 203a of the second switching transistor 203 are formed. Therefore, a drive signal is applied to each of the gate electrode 201a of the first switching transistor 201, the gate electrode 202a of the reset transistor 202, and the gate electrode 203a of the second switching transistor 203, so that the first switching transistor 201, the reset transistor 202, and the second switching transistor 203 are electrically connected on the active region 301.

The sidewall 311 is formed on a sidewall of each of the gate electrode 201a of the first switching transistor 201, the gate electrode 202a of the reset transistor 202, and the gate electrode 203a of the second switching transistor 203. The sidewall 311 includes an insulating film such as a silicon nitride film (SiN) or a silicon oxide film (SiO2), for example.

In the second embodiment of the present disclosure, the common diffusion region 312 (in FIG. 15, dots are illustrated) is formed between the gate electrode 201a of the first switching transistor 201, the gate electrode 202a of the reset transistor 202, and the gate electrode 203a of the second switching transistor 203. The common diffusion region 312 is a diffusion region in which the first FD part 211 and the second FD part 212 are connected together. The common diffusion region 312 is formed in the active region 301 after the sidewall 311 is formed in each of the gate electrode 201a of the first switching transistor 201, the gate electrode 202a of the reset transistor 202, and the gate electrode 203a of the second switching transistor 203. Therefore, the area of the common diffusion region 312 can be minimized.

The capacitance 204a of the charge accumulation part 204 is formed in the active region 302. Furthermore, the gate electrode 205a of the amplification transistor 205 and the gate electrode 206a of the selection transistor 206 are formed in an active region 303. The capacitance 204a of the charge accumulation part 204 is connected to the drain electrode of the second switching transistor 203 via a wiring layer described later. The gate electrode 205a of the amplification transistor 205 is connected to the drain electrode of the transfer transistor 111b and the drain electrode of the first switching transistor 201 via the wiring layer described later.

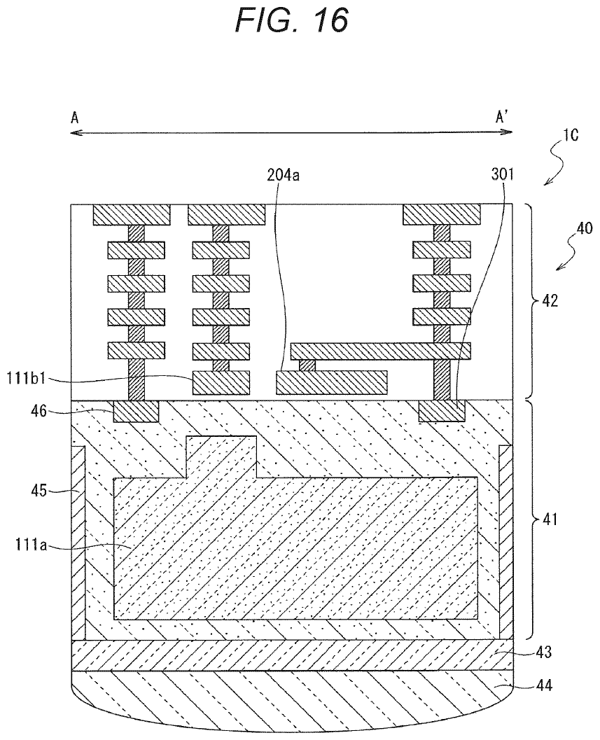

FIG. 16 is a partial longitudinal cross-sectional view illustrating an example of the semiconductor structure 40 of a schematic cross section taken along the cross section A-A′ of the unit pixel 110C illustrated in FIG. 15. In FIG. 16, the same components as those in FIG. 4 described above are denoted by the same reference signs, and detailed description thereof is omitted.

The semiconductor structure 40 of the unit pixel 110 schematically includes, for example, the photoelectric conversion layer 41 as a semiconductor layer, the wiring layer 42, the color filter 43, and the on-chip lens 44.

The on-chip lens 44 is an optical lens for efficiently condensing light incident on the photodetection device 1 from the outside and forming an image on each of the large pixels 111 (that is, the first photoelectric conversion part 111a) of the photoelectric conversion layer 41. The on-chip lens 44 is typically arranged for each of the large pixels 111.

The color filter 43 is an optical filter that selectively transmits light of a predetermined wavelength of the light condensed by the on-chip lens 44. In the present example, four color filters 43 that selectively transmit wavelengths of red light, green light, blue light, and near-infrared light are used, but the present invention is not limited thereto. The color filter 43 corresponding to any color (wavelength) is arranged in each of the large pixels 111.

The photoelectric conversion layer 41 is a functional layer in which the first photoelectric conversion part 111a, the transfer transistor 111b, and the like are formed. The first photoelectric conversion part 111a of the photoelectric conversion layer 41 generate a charge amount corresponding to the intensity of light incident via the on-chip lens 44 and the color filter 43, convert the charge amount into an electric signal, and output the electric signal as a pixel signal. Note that part of the light (for example, near-infrared light or the like) incident on an incident surface of the photoelectric conversion layer 41 can transmit a surface (that is, the front surface) opposite to the incident surface (that is, the back surface).

The photoelectric conversion layer 41 is manufactured on a silicon substrate by a semiconductor manufacturing process. The first photoelectric conversion part 111a and the transfer transistor 111b are electrically connected to a predetermined metal wiring in the wiring layer 42. Furthermore, in the photoelectric conversion layer 41, the inter-pixel separation portion 45 that separates each of the large pixels 111 can be formed. The inter-pixel separation portion 45 has, for example, a trench structure formed by etching processing. The inter-pixel separation portion 45 prevents light incident on the large pixel 111 from entering the adjacent large pixel 111. Moreover, the photoelectric conversion layer 41 is provided with the contact 46 for grounding to GND (ground) on the front surface side.

The wiring layer 42 is a layer in which a metal wiring pattern for transmitting power and various drive signals to each of the large pixels 111 in the photoelectric conversion layer 41 and transmitting pixel signals read from each of the large pixels 111 is formed. The wiring layer 42 can typically include a plurality of layers of metal wiring patterns stacked together with an interlayer insulating film interposed therebetween. Furthermore, the stacked metal wiring patterns are electrically connected via, for example, vias, as necessary. The wiring layer 42 includes, for example, metal such as aluminum (Al) or copper (Cu). On the other hand, the interlayer insulating film includes, for example, silicon oxide or the like. Moreover, the wiring layer 42 includes the readout circuit 20 and can include the gate electrode 111b1 of the transfer transistor 111b. Furthermore, the wiring layer 42 includes the polysilicon capacitance 204a of the charge accumulation part 204.

### Operation of Photodetection Device 1C

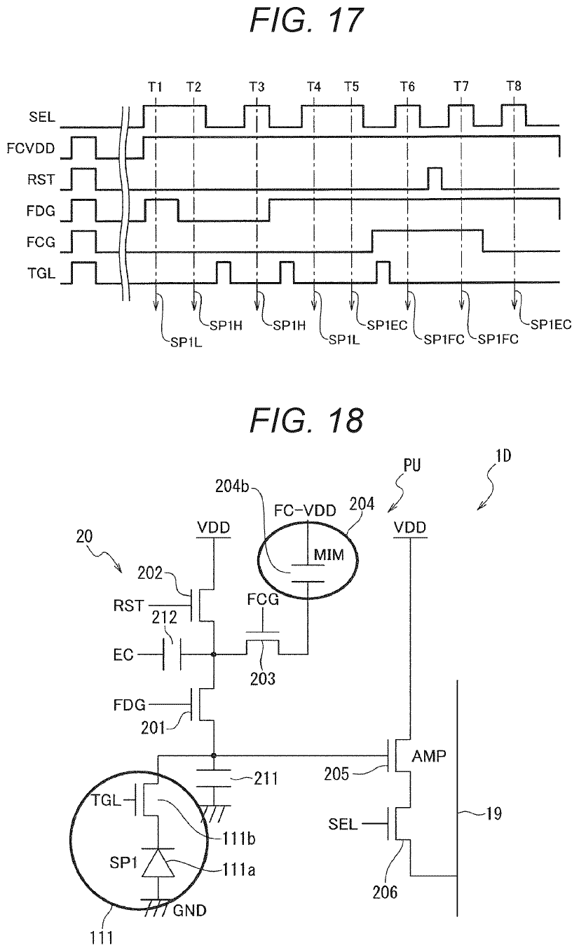

FIG. 17 is a timing chart for explaining an example of a 4AD driving operation of the readout circuit 20 of the photodetection device 1C according to the second embodiment of the present disclosure, and specifically, is a timing chart illustrating an example of readout processing of a pixel signal from the unit pixel 110. In the drawing, timing charts of the drive signals SEL, RST, FDG, TGL, FCG, and the power supply FCVDD for the unit pixel 110 are illustrated. The processing is performed in a predetermined scanning order after a predetermined time from when exposure processing is performed, for example, for each unit pixel row or each of a plurality of unit pixel rows of the pixel array section 11.

In the present embodiment, the drive signal SEL reaches a high potential level and the selection transistor 206 enters a conductive state, and the drive signal FDG reaches a high potential level and the first switching transistor enters a conductive state.

Next, at time T1, a pixel signal SP1L based on the potential due to the coupling between the first FD part 211 and the second FD part 212 is output to the vertical signal line 19 via the amplification transistor 205 and the selection transistor 206. Note that the pixel signal SP1L is a potential level in an initial state immediately after the start of reading.

Next, at time T2, the drive signal FDG reaches a low potential level, and the first switching transistor 201 enters a non-conductive state. As a result, the potential coupling between the first FD part 211 and the second FD part 212 is released. Then, a pixel signal SP1H based on the potential of the first FD part 211 is output to the vertical signal line 19 via the amplification transistor 205 and the selection transistor 206.

Next, the drive signal SEL reaches a low potential level, and the selection transistor 206 enters a non-conductive state. As a result, reading of the pixel signal from the unit pixel 110C is temporarily stopped.

Next, the drive signal TGL reaches a high potential level, and the transfer transistor 111b enters a conductive state. As a result, the charge generated and accumulated in the first photoelectric conversion part 111a during the exposure period is transferred to the first FD part 211 via the transfer transistor 111b.

Next, the drive signal TGL reaches a low potential level, and the transfer transistor 111b enters a non-conductive state. As a result, the transfer of the charge from the first photoelectric conversion part 111a to the first FD part 211 is stopped, and preparation for reading the pixel signal based on the charge of the first FD part 211 is completed.

Next, the drive signal SEL reaches a high potential level, and the selection transistor 206 enters a conductive state.

Next, at time T3, a pixel signal SP1H based on the potential of the first FD part 211 is output to the vertical signal line 19 via the amplification transistor 205 and the selection transistor 206. The pixel signal SP1H is a D-phase pixel signal for the P-phase pixel signal SP1H read at time T2, which is generated by the first photoelectric conversion part 111a during the exposure period and is based on the charge accumulated in the first FD part 211.

Next, the drive signal SEL reaches a low potential level and the selection transistor 206 enters a non-conductive state, and the drive signal FDG reaches a high potential level and the first switching transistor 201 enters a conductive state. As a result, reading of the pixel signal from the unit pixel 110 is temporarily stopped, and the potential of the first FD part 211 and the potential of the second FD part 212 are coupled.

Next, the drive signal TGL reaches a high potential level, and the transfer transistor 111b enters a conductive state. As a result, charges that has not been transferred from the first photoelectric conversion part 111a is transferred to the region coupled with the first FD part 211 and the second FD part 212 via the transfer transistor 111b.

Next, the drive signal TGL reaches a low potential level, and the transfer transistor 111b reaches a low potential level. As a result, the transfer of the remaining charges from the first photoelectric conversion part 111a to the region where the first FD part 211 and the second FD part 212 are coupled is stopped.

Next, the drive signal SEL reaches a high potential level, and the selection transistor 206 enters a conductive state.

Next, at time T4, a pixel signal SP1L based on the potential due to the coupling between the first FD part 211 and the second FD part 212 is output to the vertical signal line 19 via the amplification transistor 205 and the selection transistor 206. The pixel signal SP1L is a D-phase pixel signal for the P-phase pixel signal SP1L output at time T1.

Next, at time T5, a pixel signal SP1EC based on the potential due to the coupling between the first FD part 211 and the second FD part 212 is output to the vertical signal line 19 via the amplification transistor 205 and the selection transistor 206. The pixel signal SP1EC is a D-phase pixel signal for a P-phase pixel signal SP1EC output at time T8 described later.

Next, the drive signal SEL reaches a low potential level, and the selection transistor 206 enters a non-conductive state.

Next, the drive signal FCG reaches a high potential level, and the second switching transistor 203 enters a conductive state. As a result, the potential of the first FD part 211, the potential of the second FD part 212, and the potential of the charge accumulation part 204 are coupled.

Next, the drive signal SEL reaches a high potential level, and the selection transistor 206 enters a conductive state. Subsequently, at time T6, a D-phase pixel signal SP1FC based on the potential due to the coupling of the first FD part 211, the second FD part 212, and the charge accumulation part 204 is output to the vertical signal line 19 via the amplification transistor 205 and the selection transistor 206.

Next, the drive signal SEL reaches a low potential level, and the selection transistor 206 enters a non-conductive state.

Next, the drive signal RST reaches a high potential level, and the reset transistor 202 enters a conductive state. As a result, the potential of the region where the first FD part 211 and the second FD part 212 are coupled is reset to the level of the power supply voltage VDD.

Next, the drive signal RST reaches a low potential level, and the reset transistor 202 enters a non-conductive state.

Next, the drive signal SEL reaches a high potential level, and the selection transistor 206 enters a conductive state.

Subsequently, at time T7, a pixel signal SP1FC based on the potential due to the coupling of the first FD part 211, the second FD part 212, and the charge accumulation part 204 is output to the vertical signal line 19 via the amplification transistor 205 and the selection transistor 206. The pixel signal SP1FC is a P-phase pixel signal for the D-phase pixel signal SP1FC output at time T6.

Next, the drive signal SEL reaches a low potential level, and the selection transistor 206 enters a non-conductive state.

Next, the drive signal FCG reaches a low potential level, and the second switching transistor 203 enters a non-conductive state. As a result, the potential coupling of the first FD part 211, the second FD part 212, and the charge accumulation part 204 is released.

Next, the drive signal SEL reaches a high potential level, and the selection transistor 206 enters a conductive state.

Next, at time T8, a pixel signal SP1EC based on the potential due to the coupling between the first FD part 211 and the second FD part 212 is output to the vertical signal line 19 via the amplification transistor 205 and the selection transistor 206. The pixel signal SP1EC is a P-phase pixel signal for the D-phase pixel signal SP1EC output at time T5.

### Effects Produced by Second Embodiment

As described above, according to the second embodiment, similarly to the first embodiment described above, the first FD part 211 formed in the photoelectric conversion layer 41 and the second FD part 212 are connected to form one common diffusion region 312 in the active region 301, so that the area of the common diffusion region 312 can be reduced with respect to the layout in which the first FD part 211 and the second FD part 212 are coupled via the wiring layer 42, and the FD dark current can be reduced.

### First Modification of Second Embodiment

FIG. 18 is a circuit diagram illustrating a configuration example of a pixel unit PU of a photodetection device 1D according to a first modification of the second embodiment of the present disclosure. In FIG. 18, the same components as those in FIG. 14 described above are denoted by the same reference signs, and detailed description thereof is omitted.

In the first modification, the charge accumulation part 204 includes the metal insulator metal (MIM) capacitance 204b.

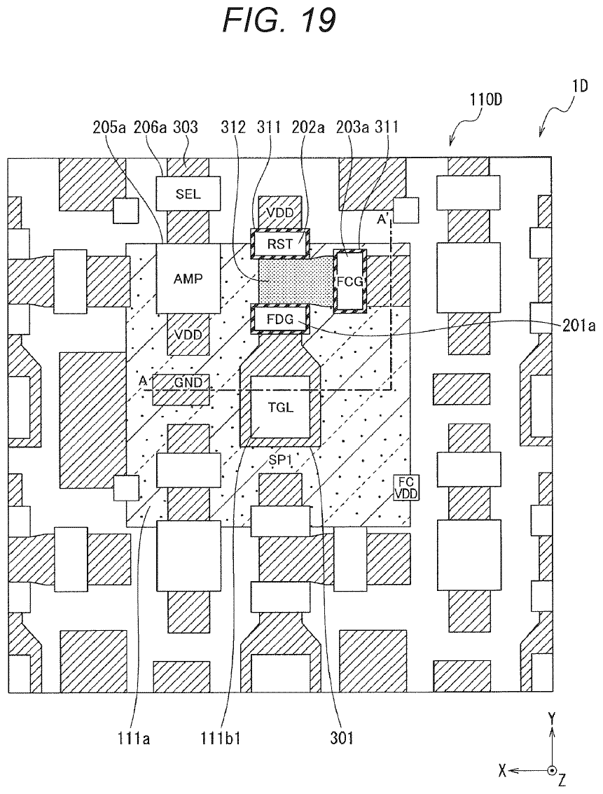

FIG. 19 is a view for explaining an example of a planar layout of each element constituting a unit pixel 110D in the pixel array section 11 of the photodetection device 1D according to the first modification of the second embodiment of the present disclosure. In FIG. 19, the same components as those in FIG. 15 described above are denoted by the same reference signs, and detailed description thereof is omitted.

In the first modification, since the MIM capacitance 204b is formed using the metal wiring pattern of the wiring layer 42, the active region 302 is unnecessary.

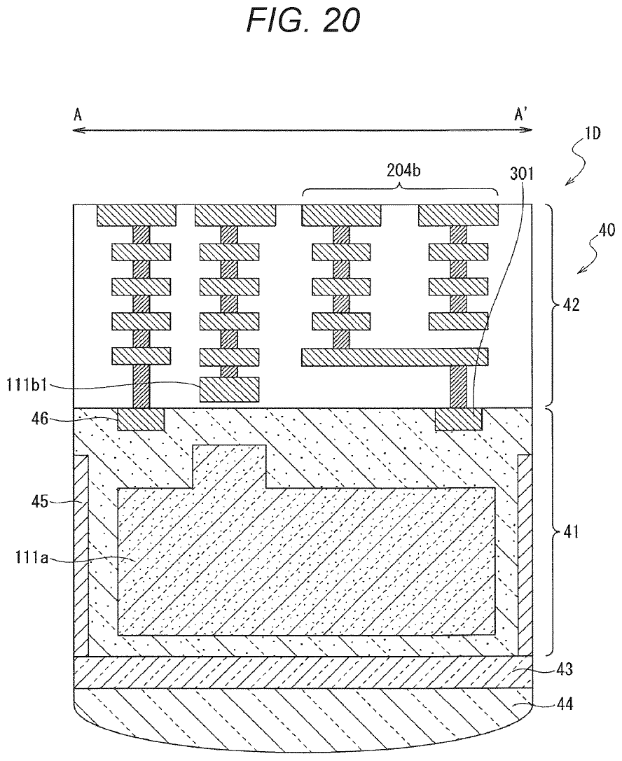

Furthermore, FIG. 20 is a partial longitudinal cross-sectional view illustrating an example of a semiconductor structure of a schematic cross section taken along the cross section A-A′ of the unit pixel 110D illustrated in FIG. 19. In FIG. 20, the same components as those in FIG. 16 described above are denoted by the same reference signs, and detailed description thereof is omitted.

The MIM capacitance 204b includes the same material as the metal wiring pattern of the wiring layer 42.

### Effects Produced by First Modification of Second Embodiment

As described above, according to the first modification of the second embodiment, effects similar to the effects produced by the second embodiment described above can be obtained.

### Second Modification of Second Embodiment

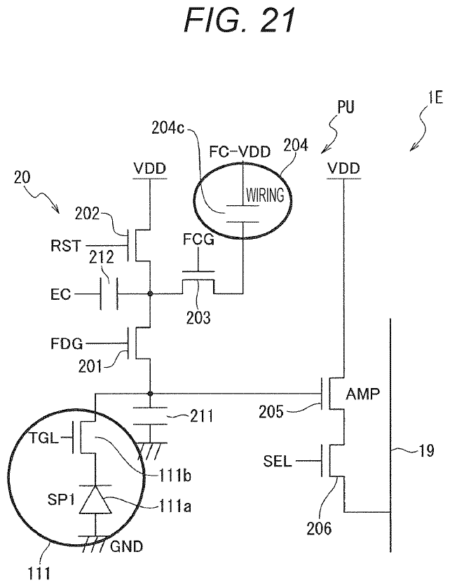

FIG. 21 is a circuit diagram illustrating a configuration example of a pixel unit PU of a photodetection device 1B according to a second modification of the second embodiment of the present disclosure. In FIG. 11, the same components as those in FIG. 14 described above are denoted by the same reference signs, and detailed description thereof is omitted.

In the second modification, the charge accumulation part 204 includes the wiring capacitance 204c.

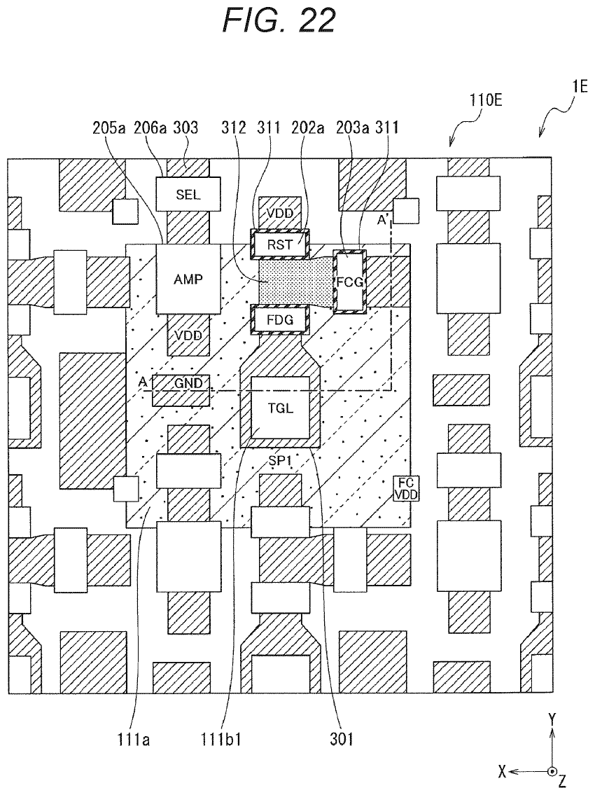

FIG. 22 is a view for explaining an example of a planar layout of each element constituting a unit pixel 110E in the pixel array section 11 of the photodetection device 1E according to the second modification of the second embodiment of the present disclosure. In FIG. 22, the same components as those in FIG. 15 described above are denoted by the same reference signs, and detailed description thereof is omitted.

In the second modification, since the wiring capacitance 204c is formed using the metal wiring pattern of the wiring layer 42, the active region 302 is unnecessary.

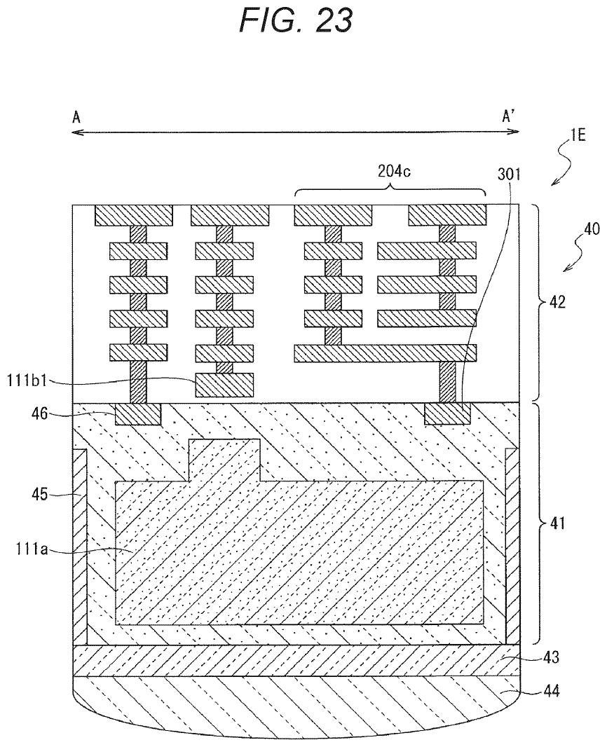

Furthermore, FIG. 23 is a partial longitudinal cross-sectional view illustrating an example of a semiconductor structure of a schematic cross section taken along the cross section A-A′ of the unit pixel 110E illustrated in FIG. 22. In FIG. 23, the same components as those in FIG. 16 described above are denoted by the same reference signs, and detailed description thereof is omitted.

The wiring capacitance 204c includes the same material as the metal wiring pattern of the wiring layer 42.

### Effects Produced by Second Modification of Second Embodiment

As described above, according to the second modification of the second embodiment, effects similar to the effects produced by the second embodiment described above can be obtained.

### Third Embodiment

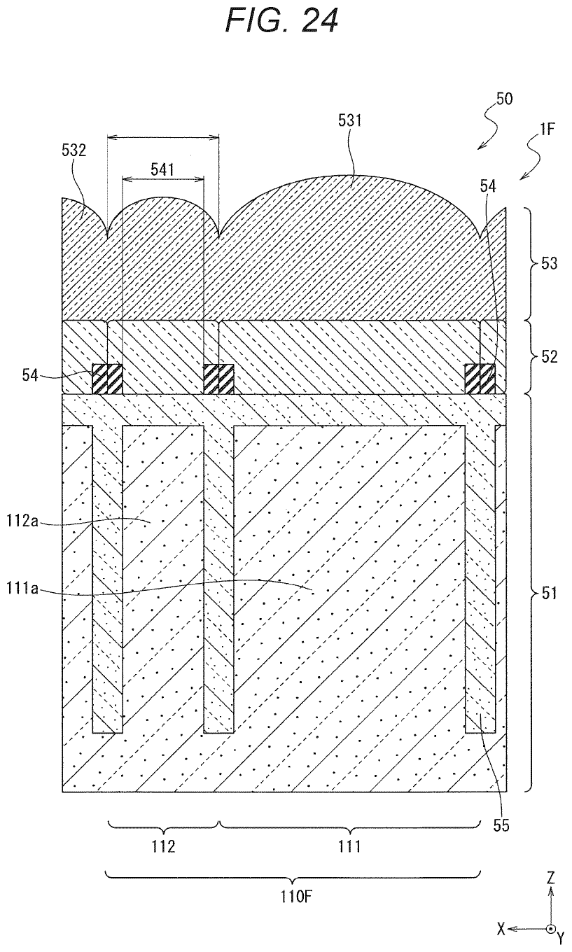

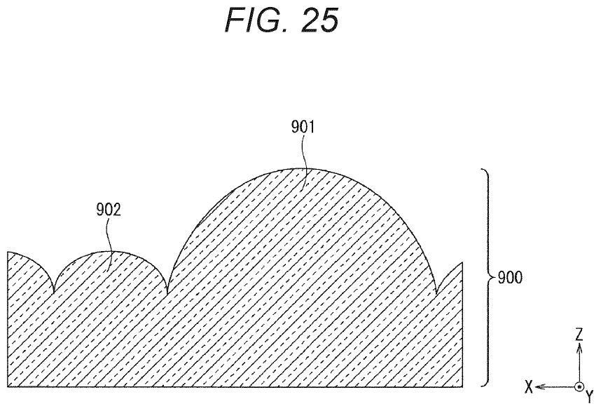

FIG. 24 is a partial longitudinal cross-sectional view illustrating an example of a semiconductor structure of a unit pixel 110F of a photodetection device 1F according to a third embodiment of the present disclosure.

A semiconductor structure 50 of the unit pixel 110F schematically includes, for example, a photoelectric conversion layer 51 as a semiconductor layer, a color filter 52, and an on-chip lens 53. Such a semiconductor structure 50 can be constituted by, for example, a silicon substrate including the photoelectric conversion layer 51.

The on-chip lens 53 includes an on-chip lens 531 for the large pixel 111 and an on-chip lens 532 for the small pixel 112, and is an optical lens for efficiently condensing light incident on the photodetection device 1F from the outside and forming an image on each of the large pixels 111 (that is, the first photoelectric conversion part 111a) and the small pixels 112 (that is, the second photoelectric conversion part 112a) of the photoelectric conversion layer 51. The on-chip lens 53 is typically arranged for each of the large pixels 111 and the small pixels 112.

The color filter 52 is an optical filter that selectively transmits light of a predetermined wavelength of the light condensed by the on-chip lens 53. In the present example, four color filters 43 that selectively transmit wavelengths of red light, green light, blue light, and near-infrared light are used, but the present invention is not limited thereto. The color filter 52 corresponding to any color (wavelength) is arranged in each of the large pixels 111 and the small pixels 112. Moreover, the color filter 52 is provided with an optical black region 54.

The photoelectric conversion layer 51 is a functional layer in which the first photoelectric conversion part 111a, the second photoelectric conversion part 112a, the transfer transistor 111b, and the like are formed. The first photoelectric conversion part 111a and the second photoelectric conversion part 112a of the photoelectric conversion layer 51 generate a charge amount corresponding to the intensity of light incident via the on-chip lens 53 and the color filter 52, convert the charge amount into an electric signal, and output the electric signal as a pixel signal. Note that part of the light (for example, near-infrared light or the like) incident on an incident surface of the photoelectric conversion layer 51 can transmit a surface (that is, the front surface) opposite to the incident surface (that is, the back surface).

The photoelectric conversion layer 51 is manufactured on a silicon substrate by a semiconductor manufacturing process. The first photoelectric conversion part 111a, the second photoelectric conversion part 112a, and the transfer transistor are electrically connected to a predetermined metal wiring in the wiring layer (not illustrated). Furthermore, in the photoelectric conversion layer 51, an inter-pixel separation portion 55 that separates the unit pixel 110F can be formed. The inter-pixel separation portion 55 has, for example, a trench structure formed by etching processing.

### Comparative Example of Third Embodiment

FIG. 25 is a partial longitudinal cross-sectional view illustrating a cross-sectional structure of an on-chip lens 900 as a comparative example of the third embodiment.

In the comparative example of the third embodiment, in order to increase the sensitivity of the large pixel 111, a thick on-chip lens 901 is provided in the large pixel 111. Then, an on-chip lens 902 thinner than the on-chip lens 901 is provided in the small pixel 112.

Therefore, in the comparative example, a difference occurs between the spectral and oblique incidence characteristics of the large pixel 111 and the spectral and oblique incidence characteristics of the small pixel, which causes coloring. In particular, as the miniaturization of the unit pixel 110F progresses, the characteristic difference becomes larger.

Moreover, if the on-chip lens 901 of the large pixel 111 is thick, optical color mixing from the large pixel 111 to the small pixel 112 increases with respect to the light incident at a high angle due to the PKG structure, and the flare resistance of the small pixel 112 decreases.

### Solution According to Third Embodiment

Therefore, in the third embodiment of the present disclosure, the lens thickness of the on-chip lens 531 of the large pixel 111 is reduced so as to have an aspect ratio equal to or less than the aspect ratio of the on-chip lens 532 of the small pixel 112. That is, the aspect ratio between the radial direction of the on-chip lens 531 (the direction indicated by the arrow X or Y in FIG. 24) and the direction orthogonal to the radial direction (the direction indicated by the arrow Z in FIG. 24) is made smaller than the aspect ratio of the on-chip lens 532. As a result, the spectral and oblique incidence characteristics of the second photoelectric conversion part 112a approach the spectral and oblique incidence characteristics of the first photoelectric conversion part 111a, and the difference decreases. Furthermore, optical color mixing of obliquely incident light from the on-chip lens 531 is reduced, and the flare resistance of the second photoelectric conversion part 112a is improved.

Furthermore, in the third embodiment of the present disclosure, the diameter of the on-chip lens 532 for the small pixel 112 is made larger than an opening width 541 of the optical black region 54.

### Method of Manufacturing On-Chip Lens in Comparative Example of Third Embodiment

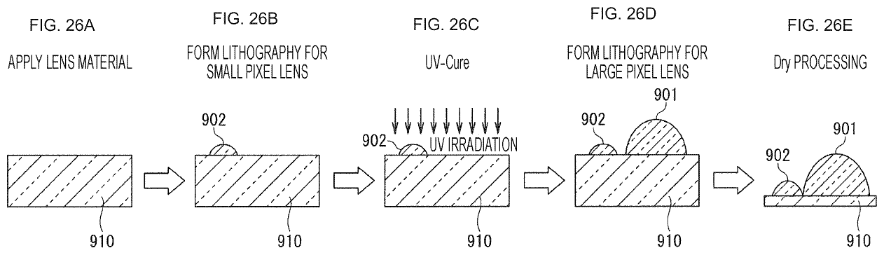

FIG. 26 is a cross-sectional view illustrating a process procedure of a method of manufacturing the on-chip lens 900 in the comparative example of the third embodiment.

First, a lens material 910 is applied (FIG. 26(a)), the on-chip lens 902 for the small pixel 112 is formed in the lens material 910 by lithography (FIG. 26(b)), and the on-chip lens 902 for the small pixel 112 is irradiated with UV (FIG. 26(c)). Subsequently, the on-chip lens 901 for the large pixel 111 is formed in the lens material 910 by lithography (FIG. 26(d)), and the lens material 910 is ground by dry processing (FIG. 26(e)).

### Method of Manufacturing On-Chip Lens in Third Embodiment

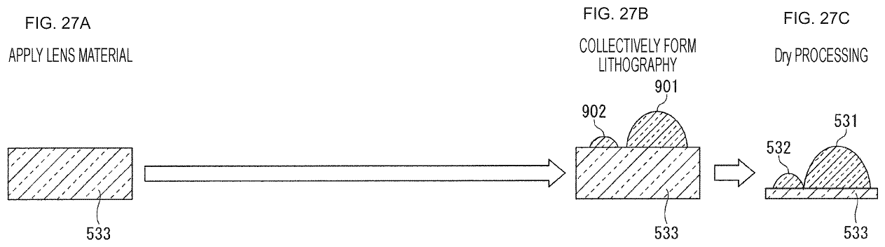

FIG. 27 is a cross-sectional view illustrating a process procedure of a method of manufacturing the on-chip lens 53 according to the third embodiment of the present disclosure.

First, a lens material 533 is applied (FIG. 27(a)), the on-chip lens 531 for the large pixel 111 and the on-chip lens 532 for the small pixel 112 are collectively formed in the lens material 533 by lithography with the KrF process (FIG. 27(b)), and the lens material 533 is ground by dry processing (FIG. 27(c)). As a result, the on-chip lens 531 for the large pixel 111 and the on-chip lens 532 for the small pixel 112 do not deviate from each other.

### Effects Produced by Third Embodiment

As described above, according to the third embodiment, by reducing the lens thickness of the on-chip lens 531 for the large pixel 111 to be smaller than the aspect ratio of the on-chip lens 532 for the small pixel 112, the spectral and oblique incidence characteristics of the second photoelectric conversion part 112a of the small pixel 112 approach the spectral and oblique incidence characteristics of the first photoelectric conversion part 111a of the large pixel 111, and the difference is reduced. Furthermore, optical color mixing of the obliquely incident light from the on-chip lens 531 of the large pixel 111 is reduced, and the flare resistance of the second photoelectric conversion part 112a is improved.

Furthermore, according to the third embodiment, by making the diameter of the on-chip lens 532 for the small pixel 112 larger than the opening width 541 of the optical black region 54, it is possible to reduce the diameter of the condensed spot determined by the diffraction limit of light in the on-chip lens 532 for the small pixel 112.

### Fourth Embodiment

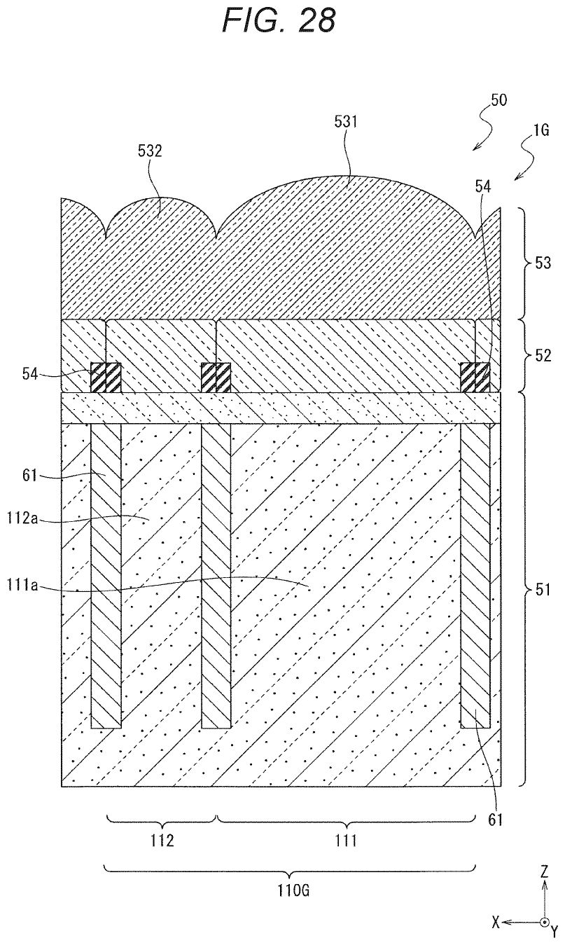

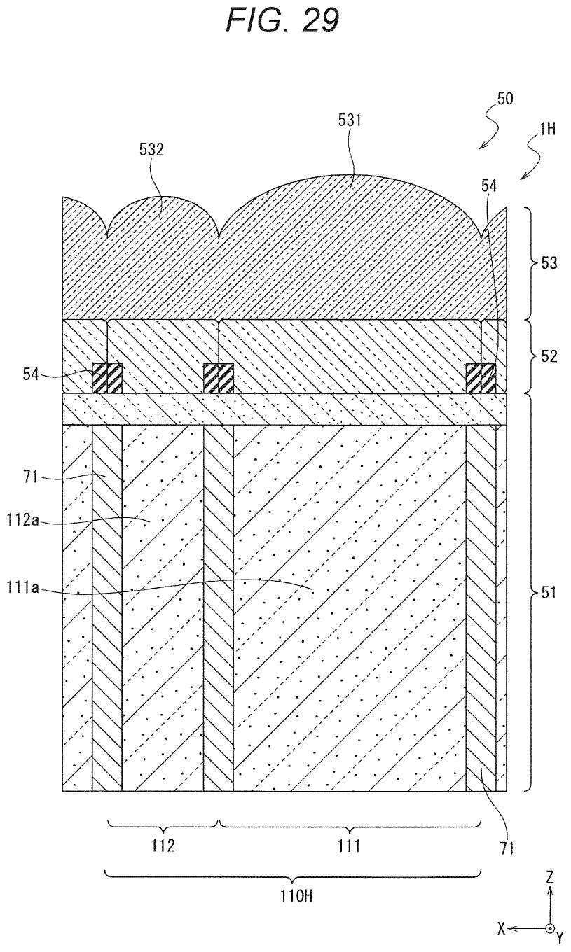

FIG. 28 is a partial longitudinal cross-sectional view illustrating an example of a semiconductor structure of a unit pixel 110G of a photodetection device 1G according to a fourth embodiment of the present disclosure. In FIG. 28, the same components as those in FIG. 24 described above are denoted by the same reference signs, and detailed description thereof is omitted.

In the semiconductor structure 50 of the unit pixel 110G, in the photoelectric conversion layer 51, an inter-pixel separation portion 61 that separates each of the large pixel 111 and the small pixel 112 can be formed. The inter-pixel separation portion 61 has a dug structure that does not penetrate the photoelectric conversion layer 51. That is, digging is performed halfway in the depth direction (direction indicated by the arrow Z in FIG. 28) from the light incident surface (back surface) of the photoelectric conversion layer 51. The inter-pixel separation portion 61 prevents light incident on the large pixel 111 from entering the adjacent small pixel 112, and prevents light incident on the small pixel 112 from entering the adjacent large pixel 111.

### Effects Produced by Fourth Embodiment

As described above, according to the fourth embodiment, effects similar to the effects produced by the third embodiment can be obtained, and by providing the non-penetrating inter-pixel separation portion 61 between the large pixel 111 and the small pixel 112, in the small pixel 112, it is possible to prevent light incident on the large pixel 111 from entering the small pixel 112, and the flare resistance of the second photoelectric conversion part 112a is improved.

### Fifth Embodiment

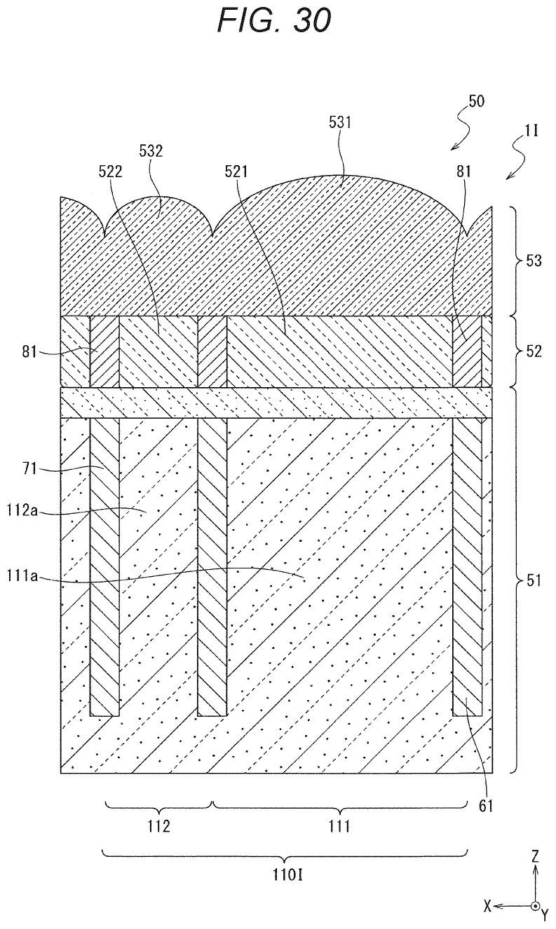

FIG. 29 is a partial longitudinal cross-sectional view illustrating an example of a semiconductor structure of a unit pixel 110H of a photodetection device 1H according to a fifth embodiment of the present disclosure. In FIG. 29, the same components as those in FIG. 24 described above are denoted by the same reference signs, and detailed description thereof is omitted.

In the semiconductor structure 50 of the unit pixel 110H, in the photoelectric conversion layer 51, an inter-pixel separation portion 71 that separates each of the large pixel 111 and the small pixel 112 can be formed. The inter-pixel separation portion 71 has a dug structure penetrating the photoelectric conversion layer 51. That is, the photoelectric conversion layer 51 is dug from the light incident surface (back surface) to the front surface thereof. The inter-pixel separation portion 71 prevents light incident on the large pixel 111 from entering the adjacent small pixel 112, and prevents light incident on the small pixel 112 from entering the adjacent large pixel 111.

### Effects Produced by Fifth Embodiment

As described above, according to the fifth embodiment, effects similar to the effects produced by the fourth embodiment described above can be obtained.

### Sixth Embodiment

FIG. 30 is a partial longitudinal cross-sectional view illustrating an example of a semiconductor structure of a unit pixel 110I of a photodetection device 1I according to a sixth embodiment of the present disclosure. In FIG. 30, the same components as those in FIG. 28 described above are denoted by the same reference signs, and detailed description thereof is omitted.

In the semiconductor structure 50 of the unit pixel 110I, the color filter 52 is configured by alternately arraying a color filter 521 for the large pixel 111 and a color filter 522 for the small pixel 112. A low refraction wall portion 81 is provided between the color filter 521 for the large pixel 111 and the color filter 522 for the small pixel 112. The low refraction wall portion 81 has a refractive index lower than that of the color filter 521 for the large pixel 111 and the color filter 522 for the small pixel 112.

### Effects Produced by Sixth Embodiment

As described above, according to the sixth embodiment, the low refraction wall portion 81 provided between the color filter 521 for the large pixel 111 and the color filter 522 for the small pixel 112 allows the light of the obliquely incident light from the on-chip lens 531 for the large pixel 111 to be reflected without being refracted, so that the flare resistance of the second photoelectric conversion part 112a of the small pixel 112 is improved.

### Seventh Embodiment

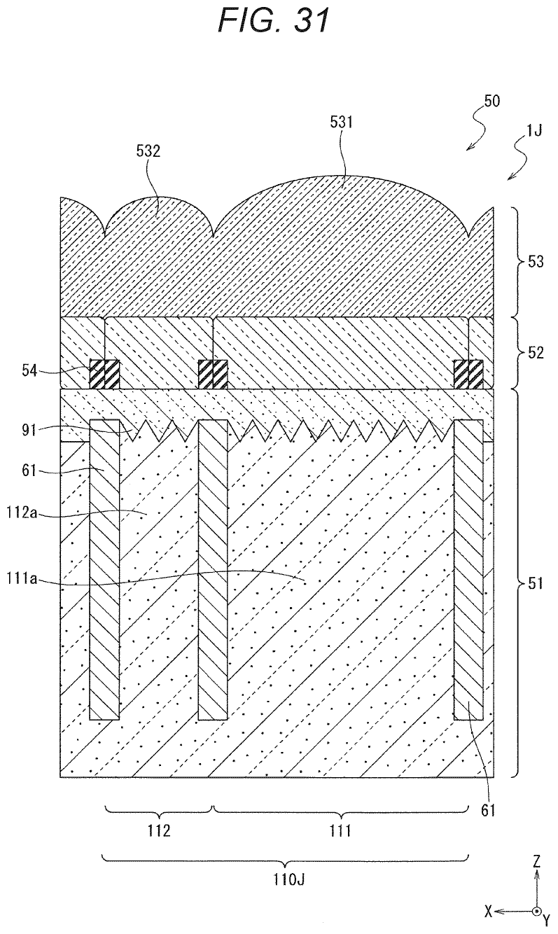

FIG. 31 is a partial longitudinal cross-sectional view illustrating an example of a semiconductor structure of a unit pixel 110J of a photodetection device 1J according to a seventh embodiment of the present disclosure. In FIG. 31, the same components as those in FIG. 28 described above are denoted by the same reference signs, and detailed description thereof is omitted.

In the semiconductor structure 50 of the unit pixel 110J, a reflection prevention portion (RIG) 91 having a moth-eye structure is formed on the light incident surface (back surface) of the photoelectric conversion layer 51. The reflection prevention portion 91 prevents reflection of light incident on the first photoelectric conversion part 111a and the second photoelectric conversion part 112a.

### Effects Produced by Seventh Embodiment

As described above, according to the seventh embodiment, the reflection prevention portion 91 having the moth-eye structure can prevent reflection of the incident light, whereby the light incident on the large pixel 111 can be prevented from entering the small pixel 112, and the flare resistance of the second photoelectric conversion part 112a of the small pixel 112 is improved.

### Other Embodiments

As described above, the present technology has been described by the first to seventh embodiments, the first modification and the second modification of the first embodiment, the first modification and the second modification of the second embodiment, but it should not be understood that the description and drawings that constitute a part of the present disclosure limit the present technology. It will be apparent to those skilled in the art that various alternative embodiments, examples, and operation techniques can be included in the present technology when understanding the spirit of the technical content disclosed in the first to seventh embodiments. Furthermore, the configurations disclosed in the first to seventh embodiments, the first modification and the second modification of the first embodiment, the first modification and the second modification of the second embodiment can be appropriately combined within a range in which no contradiction occurs. For example, configurations disclosed in a plurality of different embodiments may be combined, or configurations disclosed in a plurality of different modifications of the same embodiment may be combined.

### Application Example to Electronic Device

The photodetection device described above can be applied to various electronic devices such as, for example, an imaging device such as a digital still camera and a digital video camera, a mobile phone with an imaging function, or other devices having an imaging function.

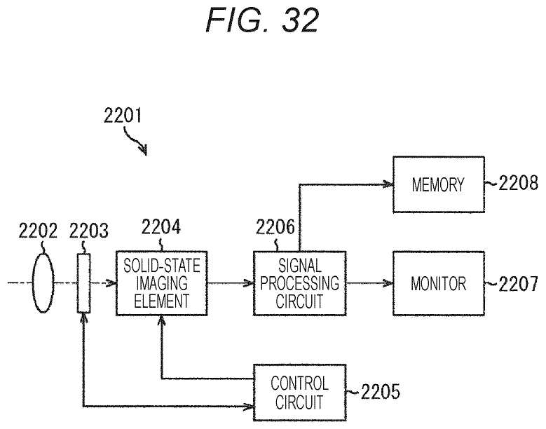

FIG. 32 is a block diagram illustrating a configuration example of the imaging device as the electronic device to which the present technology is applied.

An imaging device 2201 illustrated in FIG. 32 includes an optical system 2202, a shutter device 2203, a solid-state imaging element 2204 as a photodetection device, a control circuit 2205, a signal processing circuit 2206, a monitor 2207, and a memory 2208, and can capture a still image and a moving image.

The optical system 2202 includes one or a plurality of lenses, and guides light from a subject (incident light) to the solid-state imaging element 2204 to form an image on a light receiving surface of the solid-state imaging element 2204.

The shutter device 2203 arranged between the optical system 2202 and the solid-state imaging element 2204 controls a light emission period to the solid-state imaging element 2204 and a light-shielding period according to control of the control circuit 2205.

The solid-state imaging element 2204 includes a package including the solid-state imaging element described above. The solid-state imaging element 2204 accumulates a signal charge for a certain period according to the light the image of which is formed as an image on the light receiving surface via the optical system 2202 and the shutter device 2203. The signal charges accumulated in the solid-state imaging element 2204 are transferred according to a drive signal (timing signal) supplied from the control circuit 2205.

The control circuit 2205 outputs the drive signal to control a transfer operation of the solid-state imaging element 2204 and a shutter operation of the shutter device 2203 to drive the solid-state imaging element 2204 and the shutter device 2203.

The signal processing circuit 2206 performs various types of signal processing on the signal charges output from the solid-state imaging element 2204. An image (image data) obtained by the signal processing circuit 2206 performing the signal processing is supplied to the monitor 2207 to be displayed or supplied to the memory 2208 to be stored (recorded).

Also in the imaging device 2201 configured as described above, the photodetection devices 1, 1A, 1B, 1C, 1D, 1E, 1F, 1G, 1H, 1I, and 1J can be applied instead of the solid-state imaging element 2204 described above.

### Application Example to Mobile Body

The technology according to the present disclosure (the present technology) can be applied to various products. For example, the technology according to the present disclosure may be implemented as a device mounted on any type of mobile body such as an automobile, an electric vehicle, a hybrid electric vehicle, a motorcycle, a bicycle, a personal mobility, an airplane, a drone, a ship, a robot, and the like.

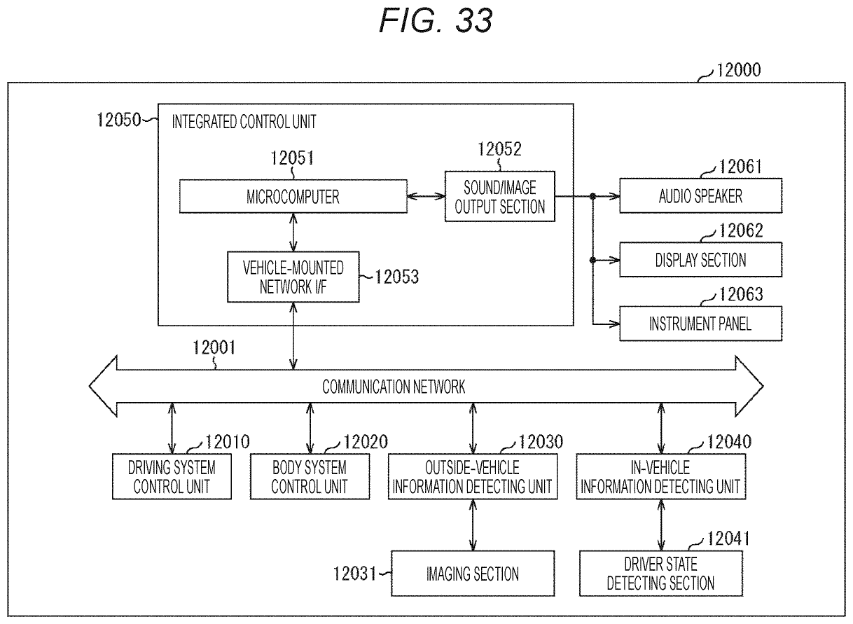

FIG. 33 is a block diagram illustrating a schematic configuration example of a vehicle control system, which is an example of a mobile object control system to which the technology according to the present disclosure can be applied.

The vehicle control system 12000 includes a plurality of electronic control units connected to each other via a communication network 12001. In the example depicted in FIG. 33, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 33, an audio speaker 12061, a display section 12062, and an instrument panel 12063 are illustrated as the output device. The display section 12062 may, for example, include at least one of an on-board display and a head-up display.

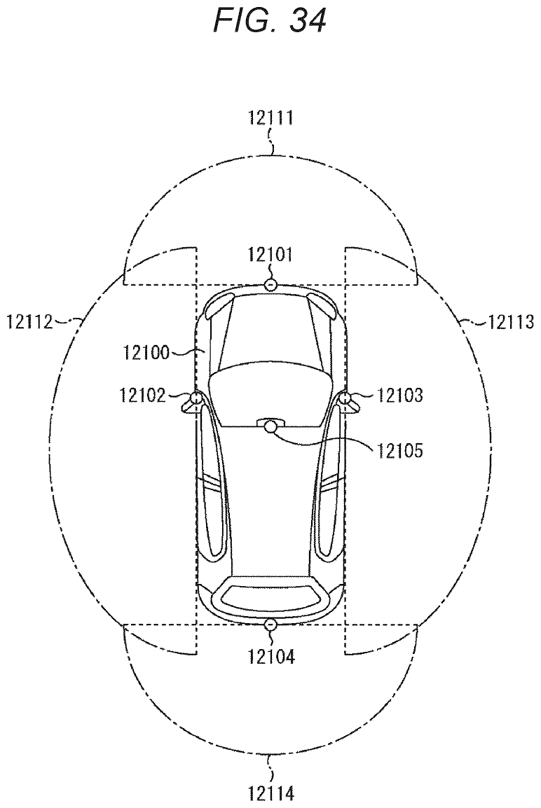

FIG. 34 is a diagram illustrating an example of the installation position of the imaging section 12031.

In FIG. 34, the vehicle 12100 includes imaging sections 12101, 12102, 12103, 12104, and 12105 as the imaging section 12031.

The imaging sections 12101, 12102, 12103, 12104, 12105 are provided, for example, at positions such as a front nose, a sideview mirror, a rear bumper, a back door, and an upper portion of a windshield in the interior of a vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a traffic signal, a traffic sign, a lane, or the like.

Note that FIG. 31 illustrates an example of the imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Note that the present disclosure can also have the following configurations.

### (1)

A photodetection device including:
a semiconductor layer in which a plurality of unit pixels having a first photoelectric conversion part that photoelectrically converts light received according to a first sensitivity and a second photoelectric conversion part that photoelectrically converts light received according to a second sensitivity is arranged in a matrix, the second sensitivity being lower than the first sensitivity; and
a wiring layer stacked on a surface of the semiconductor layer on a side opposite to a light incident surface and including a readout circuit that outputs a pixel signal based on a charge output from the unit pixel,
in which the semiconductor layer includes a common diffusion region connecting a first diffusion region capable of accumulating a charge photoelectrically converted by the first photoelectric conversion part and a second diffusion region capable of accumulating a charge photoelectrically converted by the second photoelectric conversion part in a plan view, and
the readout circuit outputs a pixel signal based on the charge from the common diffusion region.

### (2)

The photodetection device according to (1),
in which the readout circuit includes: as a pixel transistor,
a reset transistor that resets a potential of the common diffusion region to a predetermined potential;
an amplification transistor that generates, as the pixel signal, a signal of a voltage corresponding to a level of charges accumulated in the common diffusion region;
a selection transistor that controls an output timing of the pixel signal from the amplification transistor;
a first switching transistor that transfers the charge generated by the first photoelectric conversion part to the common diffusion region; and
a second switching transistor that transfers the charge generated by the second photoelectric conversion part to the common diffusion region, and
the common diffusion region is arranged between a source region of the reset transistor, a source region of the first switching transistor, and a source region of the second switching transistor in a plan view.

### (3)

The photodetection device according to (1), in which a capacitance connected to the common diffusion region is a polysilicon capacitance.

### (4)

The photodetection device according to (1), in which a capacitance connected to the common diffusion region is a metal insulator metal (MIM) capacitance.

### (5)

The photodetection device according to (1), in which a capacitance connected to the common diffusion region is a wiring capacitance.

### (6)

The photodetection device according to (1), in which the common diffusion region functions as an accumulation node during an exposure period.

### (7)

The photodetection device according to (1), in which the common diffusion region is an ion implantation region after a sidewall of a gate electrode of a pixel transistor included in the readout circuit is formed.

### (8)

The photodetection device according to (1),
in which each of the plurality of unit pixels includes:
a first on-chip lens that is provided on a light incident surface side of the semiconductor layer and condenses light from outside on the first photoelectric conversion part; and
a second on-chip lens that is provided on the light incident surface side of the semiconductor layer and condenses light from outside on the second photoelectric conversion part, and
an aspect ratio between a radial direction of the first on-chip lens and a direction orthogonal to the radial direction is smaller than an aspect ratio of the second on-chip lens.

### (9)

The photodetection device according to (8), in which a diameter of the second on-chip lens is larger than an opening width of an optical black region provided between the semiconductor layer and the second on-chip lens.

### (10)

The photodetection device according to (8),
in which the unit pixel includes a first pixel having the first photoelectric conversion part and a second pixel having the second photoelectric conversion part, and
the unit pixel has a dug structure not penetrating the semiconductor layer as a separation structure between the first pixel and the second pixel.

### (11)

The photodetection device according to (8),
in which the unit pixel includes a first pixel having the first photoelectric conversion part and a second pixel having the second photoelectric conversion part, and
the unit pixel has a dug structure penetrating the semiconductor layer as a separation structure between the first pixel and the second pixel.

### (12)

The photodetection device according to (8), further including:
a first color filter provided between a light incident surface of the semiconductor layer and the first on-chip lens;
a second color filter provided between a light incident surface of the semiconductor layer and the second on-chip lens and corresponding to a wavelength of light different from a wavelength of light of the first color filter; and
a wall portion between the first color filter and the second color filter, the wall portion having a refractive index lower than refractive indexes of the first color filter and the second color filter.

### (13)

The photodetection device according to (8), further including a reflection prevention portion having a moth-eye structure that prevents reflection of incident light on a light incident surface of the semiconductor layer.

### (14)

A photodetection device including:
a semiconductor layer in which a plurality of pixels each having a photoelectric conversion part that photoelectrically converts received light is arranged in a matrix; and
a wiring layer stacked on a surface of the semiconductor layer on a side opposite to a light incident surface and including a readout circuit that outputs a pixel signal based on a charge output from the pixel,
in which the semiconductor layer includes a diffusion region capable of accumulating a charge photoelectrically converted by the photoelectric conversion part,
the readout circuit includes three or more pixel transistors, the three or more pixel transistors sharing the same source region, and
the diffusion region is arranged in the source region shared by the three or more pixel transistors.

### (15)

The photodetection device according to (14),
in which the readout circuit includes: as a pixel transistor,
a reset transistor that resets a potential of the diffusion region to a predetermined potential;
an amplification transistor that generates, as the pixel signal, a signal of a voltage corresponding to a level of charges accumulated in the diffusion region;
a selection transistor that controls an output timing of the pixel signal from the amplification transistor; and
a switching transistor that transfers the charge generated by the photoelectric conversion part to the diffusion region, and
the diffusion region is arranged between a source region of the reset transistor, a source region of the switching transistor, and a source region of another pixel transistor in a plan view.

### (16)

The photodetection device according to (14), in which a capacitance connected to the diffusion region is a polysilicon capacitance.

### (17)

The photodetection device according to (14), in which a capacitance connected to the diffusion region is a metal insulator metal (MIM) capacitance.

### (18)

The photodetection device according to (14), in which a capacitance connected to the diffusion region is a wiring capacitance.

### (19)

The photodetection device according to (14), in which the diffusion region functions as an accumulation node during an exposure period.

### (20)

The photodetection device according to (14), in which the diffusion region is an ion implantation region after a sidewall of a gate electrode of a pixel transistor included in the readout circuit is formed.

### (21)

An electronic device including a photodetection device, the photodetection device including:
a semiconductor layer in which a plurality of unit pixels having a first photoelectric conversion part that photoelectrically converts light received according to a first sensitivity and a second photoelectric conversion part that photoelectrically converts light received according to a second sensitivity is arranged in a matrix, the second sensitivity being lower than the first sensitivity; and
a wiring layer stacked on a surface of the semiconductor layer on a side opposite to a light incident surface and including a readout circuit that outputs a pixel signal based on a charge output from the unit pixel,
in which the semiconductor layer includes a common diffusion region connecting a first diffusion region capable of accumulating a charge photoelectrically converted by the first photoelectric conversion part and a second diffusion region capable of accumulating a charge photoelectrically converted by the second photoelectric conversion part in a plan view, and
the readout circuit outputs a pixel signal based on the charge from the common diffusion region.

### (22)

An electronic device including a photodetection device, the photodetection device including:
a semiconductor layer in which a plurality of pixels each having a photoelectric conversion part that photoelectrically converts received light is arranged in a matrix; and
a wiring layer stacked on a surface of the semiconductor layer on a side opposite to a light incident surface and including a readout circuit that outputs a pixel signal based on a charge output from the pixel,
in which the semiconductor layer includes a diffusion region capable of accumulating a charge photoelectrically converted by the photoelectric conversion part,
the readout circuit includes three or more pixel transistors, the three or more pixel transistors sharing the same source region, and
the diffusion region is arranged in the source region shared by the three or more pixel transistors.

### REFERENCE SIGNS LIST

1, 1A, 1B, 1C, 1D, 1E, 1F, 1H, 1I, 1J Photodetection device
11 Pixel array section
11b1 Gate electrode
12 Vertical drive section
13 Column processing section
14 Horizontal drive section
15 System control section
16 Signal processing section
17 Data storage section
18 Pixel drive line
19 Vertical signal line
20 Readout circuit
40, 50 Semiconductor structure
41, 51 Photoelectric conversion layer
42 Wiring layer
43, 52 Color filter
44, 53 On-chip lens
45 Inter-pixel separation portion
46 Contact
54 Optical black region
55, 61, 71 Inter-pixel separation portion
81 Low refraction wall portion
91 Reflection prevention portion
110, 110A, 110B, 110C, 110D, 110E, 110F, 110G, 110H, 110I, 110J Unit pixel
111 Large pixel
111a First photoelectric conversion part
111b Transfer transistor
111b1 Gate electrode
112 Small pixel
112a Second photoelectric conversion part
201 First switching transistor
201a Gate electrode
202 Reset transistor
202a Gate electrode
203 Second switching transistor
203a Gate electrode
204 Charge accumulation part
204a Polysilicon capacitance
204b MIM capacitance
204c Wiring capacitance
205 Amplification transistor
205a Gate electrode
206 Selection transistor
206a Gate electrode
211 First FD part
212 Second FD part
301, 302, 303 Active region
311 Sidewall
312 Common diffusion region
521, 522 Color filter
531, 532, 900, 901, 902 On-chip lens
533 Lens material
541 Opening width
910 Lens material
2201 Imaging device
2202 Optical system
2203 Shutter device
2204 Solid-state imaging element
2205 Control circuit
2206 Signal processing circuit
2207 Monitor
2208 Memory
12000 Vehicle control system
12001 Communication network
12010 Driving system control unit
12020 Body system control unit
12030 Outside-vehicle information detecting unit
12031 Imaging section
12040 In-vehicle information detecting unit
12041 Driver state detecting section
12050 Integrated control unit
12051 Microcomputer
12052 Sound/image output section
12061 Audio speaker
12062 Display section
12063 Instrument panel
12100 Vehicle
12101 to 12105 Imaging section
12111 to 12114 Imaging range

1. A photodetection device comprising:
a semiconductor layer in which a plurality of unit pixels having a first photoelectric conversion part that photoelectrically converts light received according to a first sensitivity and a second photoelectric conversion part that photoelectrically converts light received according to a second sensitivity is arranged in a matrix, the second sensitivity being lower than the first sensitivity; and
a wiring layer stacked on a surface of the semiconductor layer on a side opposite to a light incident surface and including a readout circuit that outputs a pixel signal based on a charge output from the unit pixel,
wherein the semiconductor layer includes a common diffusion region connecting a first diffusion region capable of accumulating a charge photoelectrically converted by the first photoelectric conversion part and a second diffusion region capable of accumulating a charge photoelectrically converted by the second photoelectric conversion part in a plan view, and
the readout circuit outputs a pixel signal based on the charge from the common diffusion region.

2. The photodetection device according to claim 1,
wherein the readout circuit includes: as a pixel transistor,
a reset transistor that resets a potential of the common diffusion region to a predetermined potential;
an amplification transistor that generates, as the pixel signal, a signal of a voltage corresponding to a level of charges accumulated in the common diffusion region;
a selection transistor that controls an output timing of the pixel signal from the amplification transistor;
a first switching transistor that transfers the charge generated by the first photoelectric conversion part to the common diffusion region; and
a second switching transistor that transfers the charge generated by the second photoelectric conversion part to the common diffusion region, and
the common diffusion region is arranged between a source region of the reset transistor, a source region of the first switching transistor, and a source region of the second switching transistor in a plan view.

3. The photodetection device according to claim 1, wherein a capacitance connected to the common diffusion region is a polysilicon capacitance.

4. The photodetection device according to claim 1, wherein a capacitance connected to the common diffusion region is a metal insulator metal (MIM) capacitance.

5. The photodetection device according to claim 1, wherein a capacitance connected to the common diffusion region is a wiring capacitance.

6. The photodetection device according to claim 1, wherein the common diffusion region functions as an accumulation node during an exposure period.

7. The photodetection device according to claim 1, wherein the common diffusion region is an ion implantation region after a sidewall of a gate electrode of a pixel transistor included in the readout circuit is formed.

8. The photodetection device according to claim 1,
wherein each of the plurality of unit pixels includes:
a first on-chip lens that is provided on a light incident surface side of the semiconductor layer and condenses light from outside on the first photoelectric conversion part; and
a second on-chip lens that is provided on the light incident surface side of the semiconductor layer and condenses light from outside on the second photoelectric conversion part, and
an aspect ratio between a radial direction of the first on-chip lens and a direction orthogonal to the radial direction is smaller than an aspect ratio of the second on-chip lens.

9. The photodetection device according to claim 8, wherein a diameter of the second on-chip lens is larger than an opening width of an optical black region provided between the semiconductor layer and the second on-chip lens.

10. The photodetection device according to claim 8,
wherein the unit pixel includes a first pixel having the first photoelectric conversion part and a second pixel having the second photoelectric conversion part, and
the unit pixel has a dug structure not penetrating the semiconductor layer as a separation structure between the first pixel and the second pixel.

11. The photodetection device according to claim 8,
wherein the unit pixel includes a first pixel having the first photoelectric conversion part and a second pixel having the second photoelectric conversion part, and
the unit pixel has a dug structure penetrating the semiconductor layer as a separation structure between the first pixel and the second pixel.

12. The photodetection device according to claim 8, further comprising:
a first color filter provided between a light incident surface of the semiconductor layer and the first on-chip lens;
a second color filter provided between a light incident surface of the semiconductor layer and the second on-chip lens and corresponding to a wavelength of light different from a wavelength of light of the first color filter; and
a wall portion between the first color filter and the second color filter, the wall portion having a refractive index lower than refractive indexes of the first color filter and the second color filter.

13. The photodetection device according to claim 8, further comprising a reflection prevention portion having a moth-eye structure that prevents reflection of incident light on a light incident surface of the semiconductor layer.

14. A photodetection device comprising:
a semiconductor layer in which a plurality of pixels each having a photoelectric conversion part that photoelectrically converts received light is arranged in a matrix; and
a wiring layer stacked on a surface of the semiconductor layer on a side opposite to a light incident surface and including a readout circuit that outputs a pixel signal based on a charge output from the pixel,
wherein the semiconductor layer includes a diffusion region capable of accumulating a charge photoelectrically converted by the photoelectric conversion part,
the readout circuit includes three or more pixel transistors, the three or more pixel transistors sharing the same source region, and
the diffusion region is arranged in the source region shared by the three or more pixel transistors.

15. The photodetection device according to claim 14,
wherein the readout circuit includes: as a pixel transistor,
a reset transistor that resets a potential of the diffusion region to a predetermined potential;
an amplification transistor that generates, as the pixel signal, a signal of a voltage corresponding to a level of charges accumulated in the diffusion region;
a selection transistor that controls an output timing of the pixel signal from the amplification transistor; and
a switching transistor that transfers the charge generated by the photoelectric conversion part to the diffusion region, and
the diffusion region is arranged between a source region of the reset transistor, a source region of the switching transistor, and a source region of another pixel transistor in a plan view.

16. The photodetection device according to claim 14, wherein a capacitance connected to the diffusion region is a polysilicon capacitance.

17. The photodetection device according to claim 14, wherein a capacitance connected to the diffusion region is a metal insulator metal (MIM) capacitance.

18. The photodetection device according to claim 14, wherein a capacitance connected to the diffusion region is a wiring capacitance.

19. The photodetection device according to claim 14, wherein the diffusion region functions as an accumulation node during an exposure period.

20. The photodetection device according to claim 14, wherein the diffusion region is an ion implantation region after a sidewall of a gate electrode of a pixel transistor included in the readout circuit is formed.

21. An electronic device comprising a photodetection device, the photodetection device including:
a semiconductor layer in which a plurality of unit pixels having a first photoelectric conversion part that photoelectrically converts light received according to a first sensitivity and a second photoelectric conversion part that photoelectrically converts light received according to a second sensitivity is arranged in a matrix, the second sensitivity being lower than the first sensitivity; and
a wiring layer stacked on a surface of the semiconductor layer on a side opposite to a light incident surface and including a readout circuit that outputs a pixel signal based on a charge output from the unit pixel,
wherein the semiconductor layer includes a common diffusion region connecting a first diffusion region capable of accumulating a charge photoelectrically converted by the first photoelectric conversion part and a second diffusion region capable of accumulating a charge photoelectrically converted by the second photoelectric conversion part in a plan view, and
the readout circuit outputs a pixel signal based on the charge from the common diffusion region.

22. An electronic device comprising a photodetection device, the photodetection device including:
a semiconductor layer in which a plurality of pixels each having a photoelectric conversion part that photoelectrically converts received light is arranged in a matrix; and
a wiring layer stacked on a surface of the semiconductor layer on a side opposite to a light incident surface and including a readout circuit that outputs a pixel signal based on a charge output from the pixel,
wherein the semiconductor layer includes a diffusion region capable of accumulating a charge photoelectrically converted by the photoelectric conversion part,
the readout circuit includes three or more pixel transistors, the three or more pixel transistors sharing the same source region, and
the diffusion region is arranged in the source region shared by the three or more pixel transistors.
